(19) United States
(12) Patent Application Publication
(10) Pub. No.: US 2025/0089397 A1
(43) Pub. Date: Mar. 13, 2025

(54) PHOTODETECTORS AND METHODS OF FORMATION

(71) Applicant: Taiwan Semiconductor Manufacturing Company, Ltd., Hsinchu (TW)

(72) Inventors: Hau-Yan LU, Hsinchu City (TW); Chun-Yen PENG, Chiayi City (TW); YingKit Felix TSUI, Cupertino, CA (US)

(21) Appl. No.: 18/463,818

(22) Filed: Sep. 8, 2023

(51) Int. Cl. H01L 31/0352; H01L 31/0232

(52) U.S. Cl. CPC H10F 77/147; H10F 77/148; H10F 77/413

(57) ABSTRACT

A photodetector may include an absorption region that is formed to have an increasing depth (or thickness) in a direction that is approximately parallel to the direction of incident light that is to be projected onto the absorption region. The increasing depth of the absorption region in the direction that is approximately parallel with the direction of incident light enables the incident light to be more uniformly distributed along the length of the absorption region in the direction that is approximately parallel with the direction of incident light. This reduces the likelihood that a particular area of the absorption region reaches optical saturation, which may enable the photodetector to operate a sustained high photodetector sensitivity and/or a sustained high light detection performance, among other examples.

### BACKGROUND

A photodetector is a semiconductor device that is configured to receive photons of incident light and convert the photons to an electrical signal. The electrical signal may include a current (referred to as a photocurrent) and/or a voltage, among other examples. The photons generate electron/hole pairs in an absorption region of the photodetector. The electrons and holes are separated and collected at opposing doped collection regions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2E are diagrams of example implementations of a photodetector described herein.

FIGS. 3A-3C are diagrams of an example implementation of a photodetector device described herein.

FIGS. 4A-4W are diagrams of an example implementation of forming a photodetector device described herein.

FIGS. 5A-5F are diagrams of example implementations of a photodetector device described herein.

FIGS. 6A-6S are diagrams of an example implementation of forming a photodetector device described herein.

FIGS. 7A-7C are diagrams of example implementations of a photodetector device described herein.

FIGS. 8A-8C are diagrams of example implementations of a photodetector device described herein.

FIG. 9 is a diagram of example components of a device described herein.

FIG. 10 is a flowchart of an example process associated with forming a photodetector device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Photodetectors have many use cases, including light detection, ranging (e.g., lidar), optical communications, and cameras, among other examples. Germanium (Ge) is sometimes used in an absorption region for a photodetector. Germanium may provide faster carrier collection, lower dark current, and/or increased bandwidth relative to other types of absorption materials such as silicon (Si), and may enable efficient integration with silicon-based circuitry. Moreover, the direct band gap of germanium is approximately 0.8 electron volts (eV), making germanium particularly suited for absorption of light in the near infrared (NIR) spectrum. Thus, germanium may be used in photodetectors to achieve superior low visible light performance.

Distribution of optical power of incident light on a photodetector may not be uniform across the absorption region of the photodetector. The nonuniformity of the optical power distribution across the absorption region may result in some areas of the absorption region reaching optical saturation while other areas of the absorption region do not reach optical saturation. Optical saturation may occur where excess charge carriers (e.g., electrons and holes) shield the built-in electric field in the absorption region. Optical saturation limits further absorption of light, meaning that the photodetector can no longer detect increasing levels of optical power once optical saturation is reached. Optical saturation may result in reduced photodetector sensitivity and reduced light detection performance for the photodetector, among other examples.

In some implementations described herein, a photodetector may include an absorption region between doped collection regions. The absorption region is formed to have an increasing depth (or thickness) in a direction that is approximately parallel to the direction of incident light that is to be projected onto the absorption region. The increasing depth of the absorption region may be realized in a stepped profile (e.g., the thickness of the absorption region increases in discrete steps), a tapered profile (e.g., the thickness of the absorption region increases in along a continuous gradient), and/or may be realized in another profile.

The increasing depth of the absorption region in the direction that is approximately parallel with the direction of incident light enables the incident light to be more uniformly distributed along the length of the absorption region in the direction that is approximately parallel with the direction of incident light (e.g., relative to an absorption region having a singular thickness). This reduces the likelihood that a particular area of the absorption region reaches optical saturation, which may enable the photodetector to operate at a sustained high photodetector sensitivity and/or a sustained high light detection performance, among other examples.

Moreover, the photodetector may be formed to include a plurality of absorption regions, each having different regions with increasing thickness in the direction that is approximately parallel to the direction of incident light. The absorption regions may be configured to absorb photons of light for particular wavelength ranges, which may further decrease the likelihood of optical saturation and/or may enable the photodetector to operate as a wavelength separator or filter.

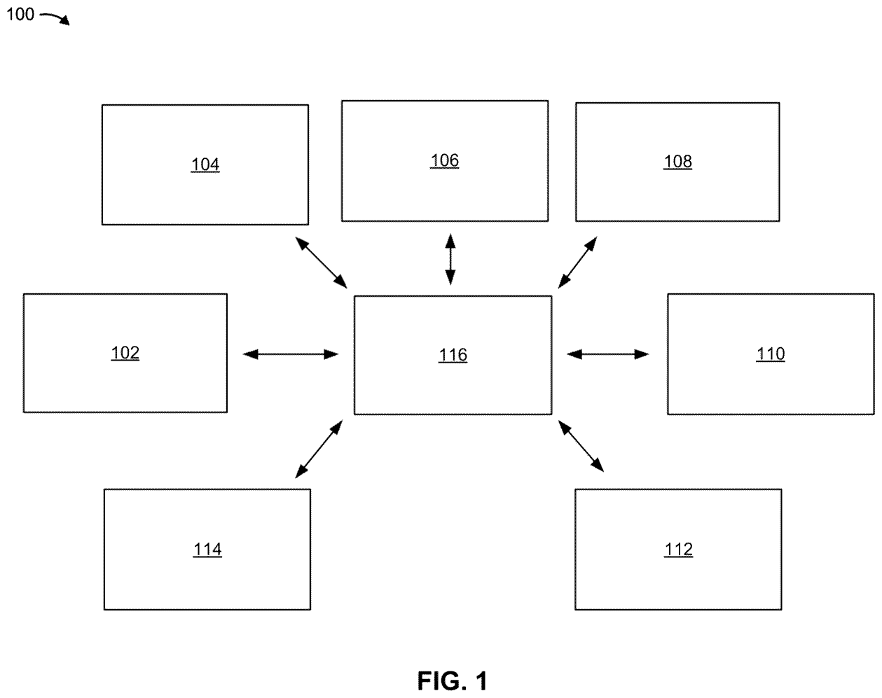

FIG. 1 is a diagram of an example environment 100 in which systems and/or methods described herein may be implemented. As shown in FIG. 1, environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, an ion implantation tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions. In some implementations, the example environment 100 includes a plurality of types of etch tools 108.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar. In some implementations, the example environment 100 includes a plurality of types of planarization tools 110 (e.g., a CMP tool, a wafer grinding tool).

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

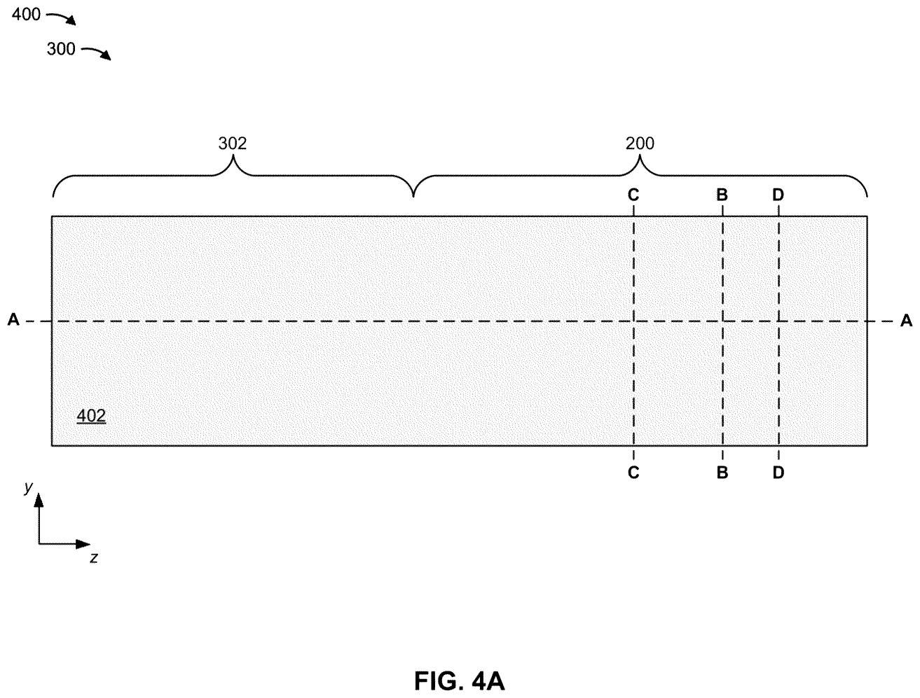

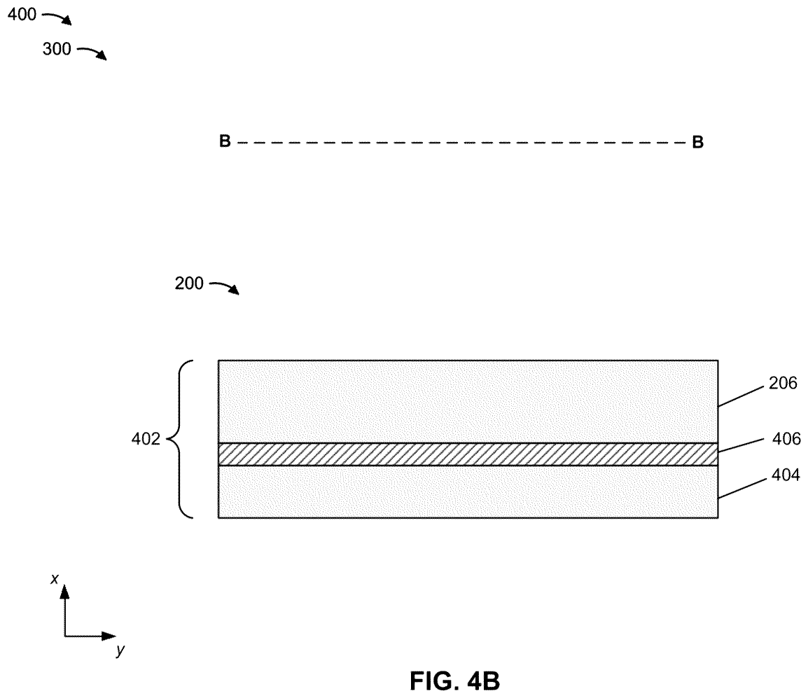

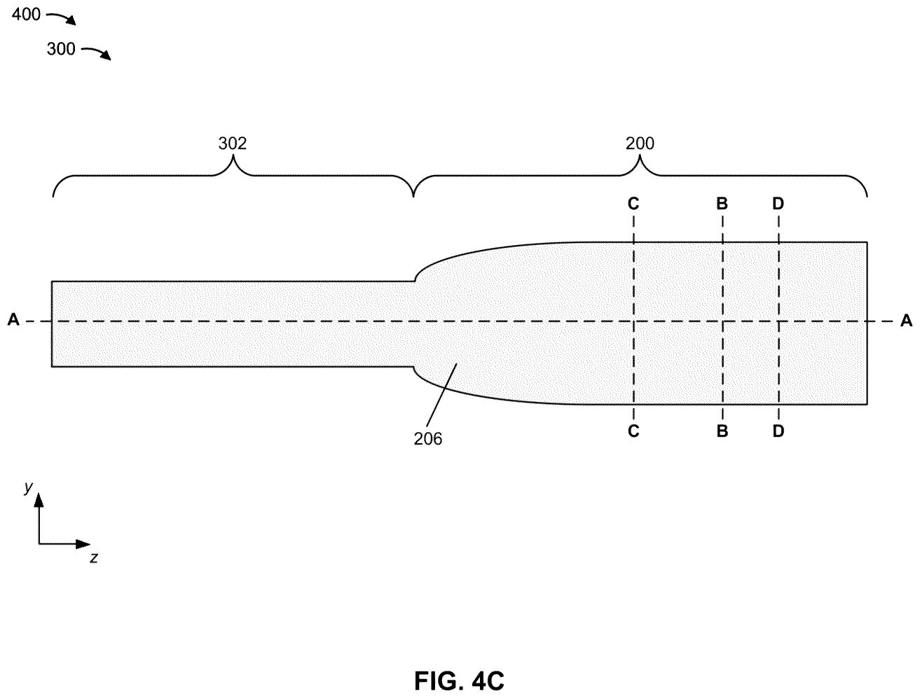

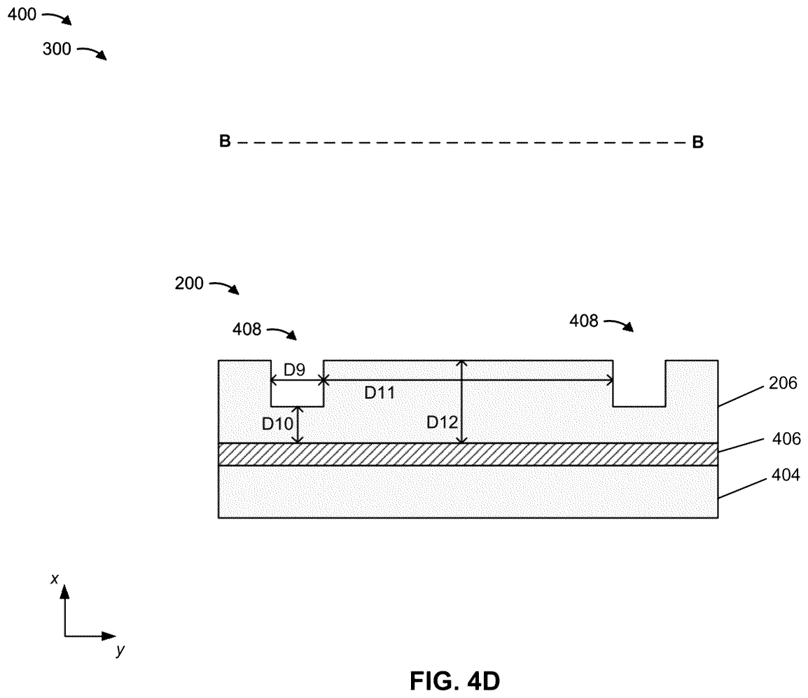

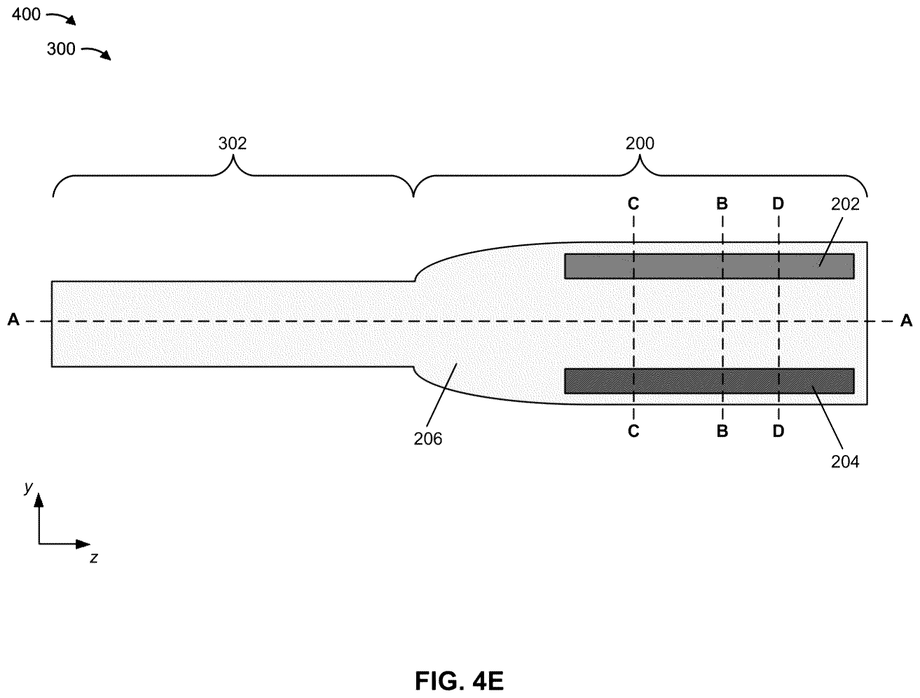

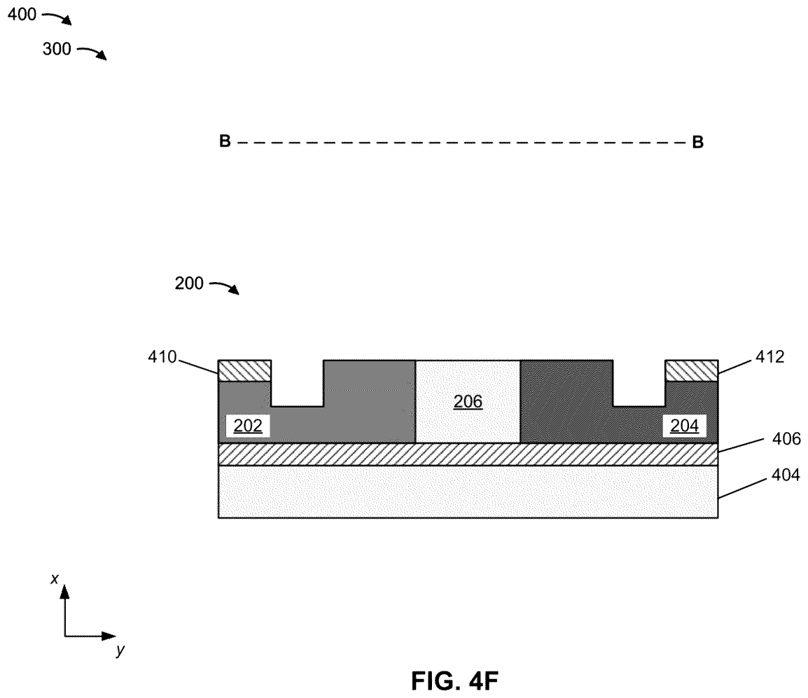

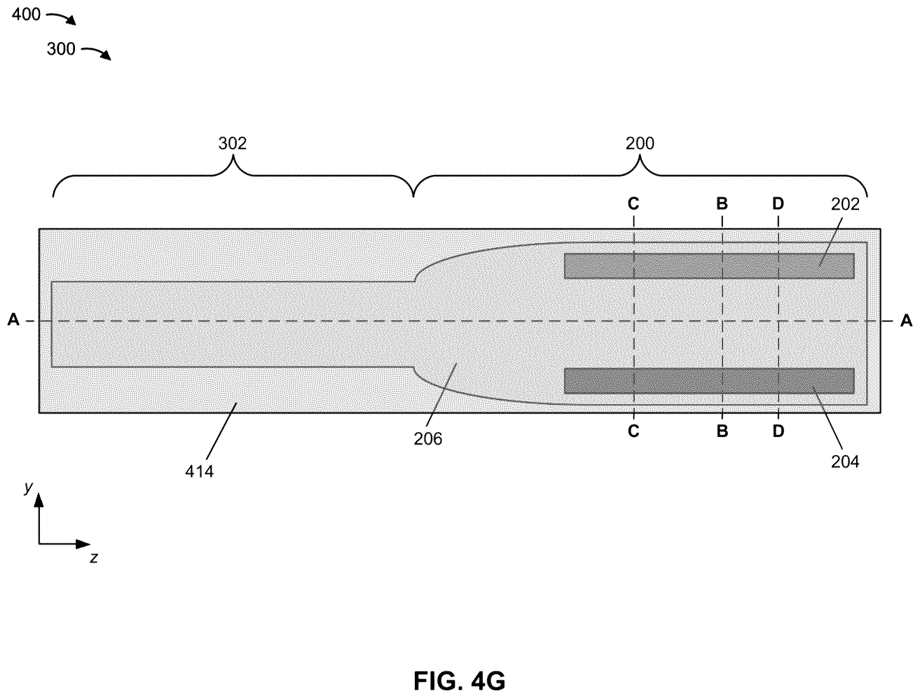

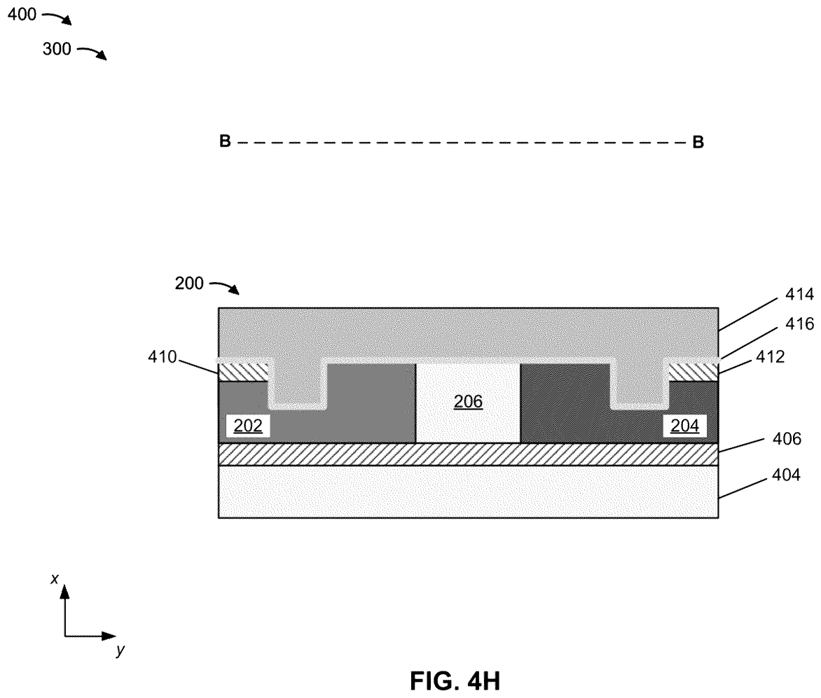

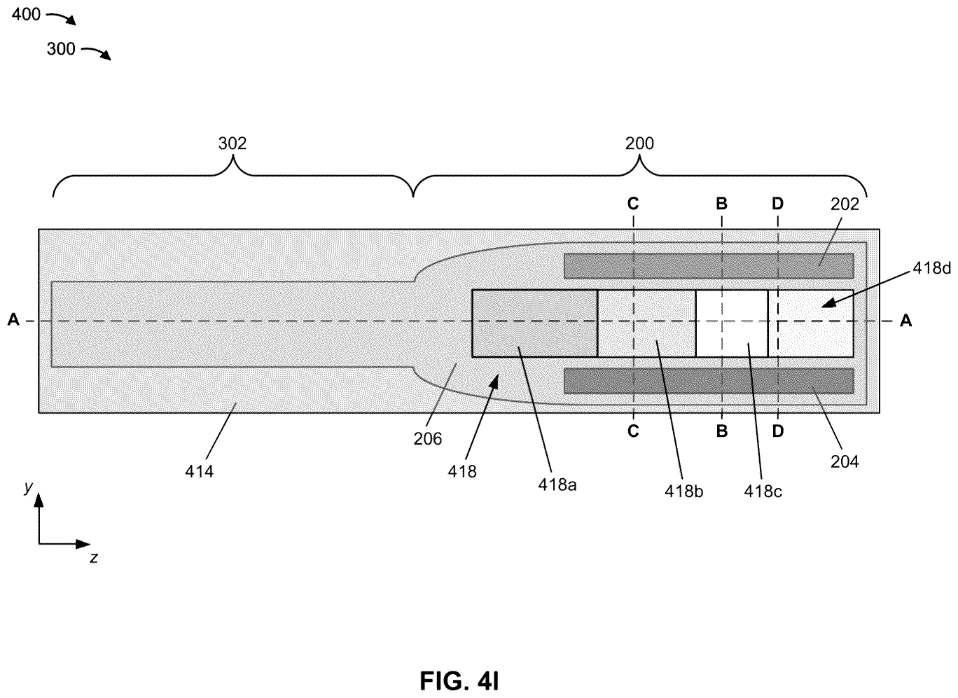

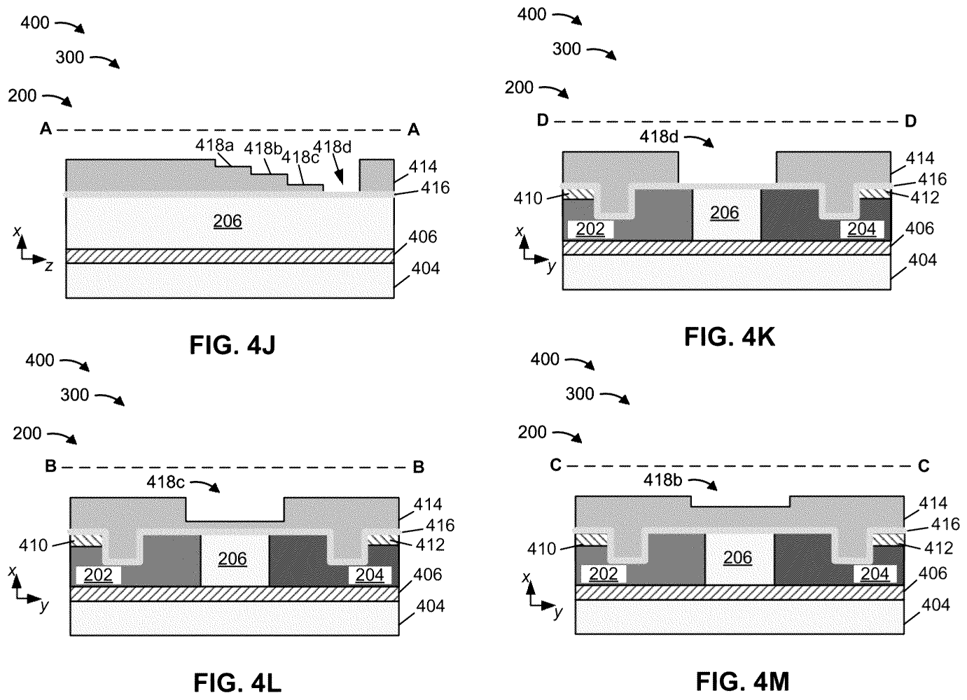

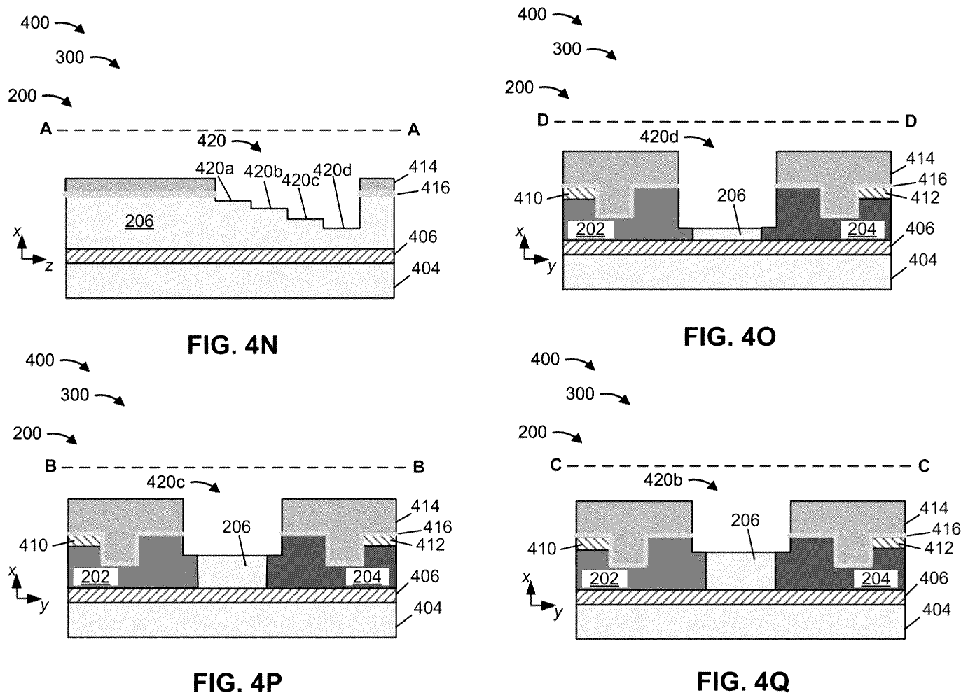

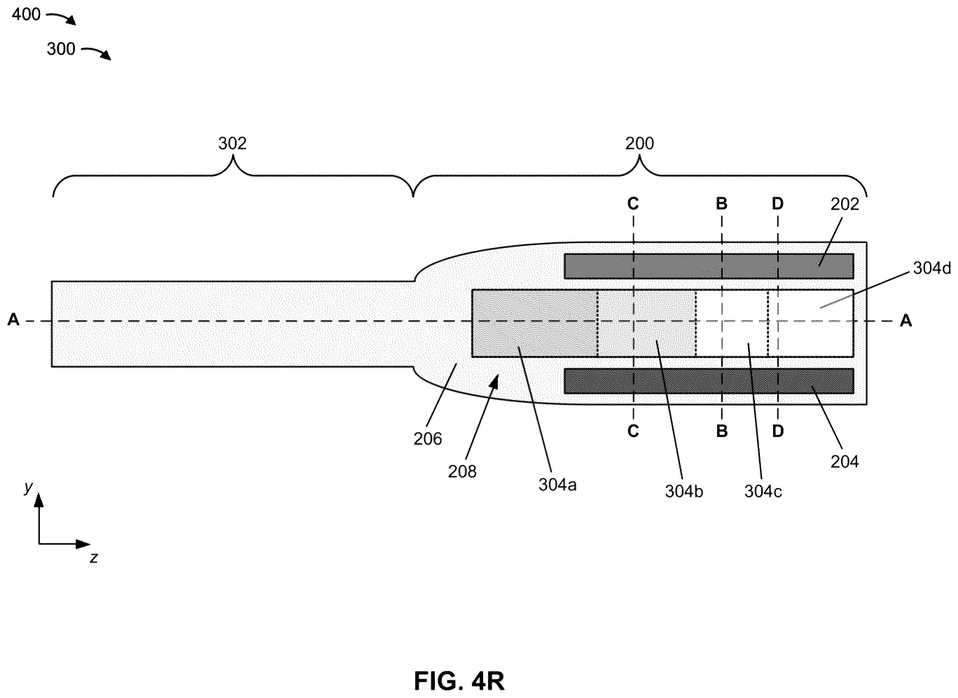

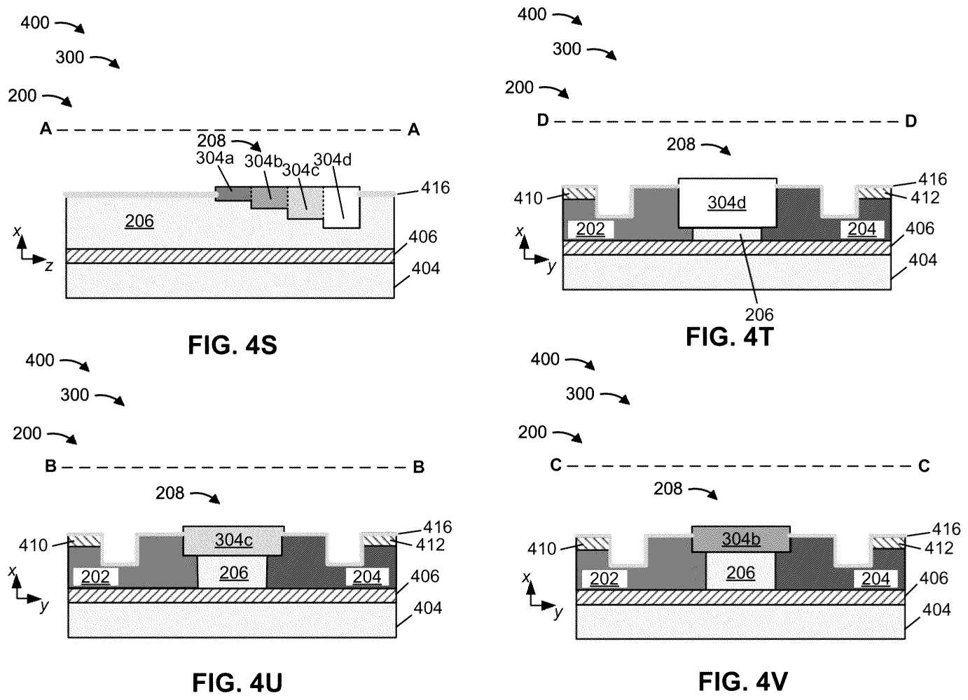

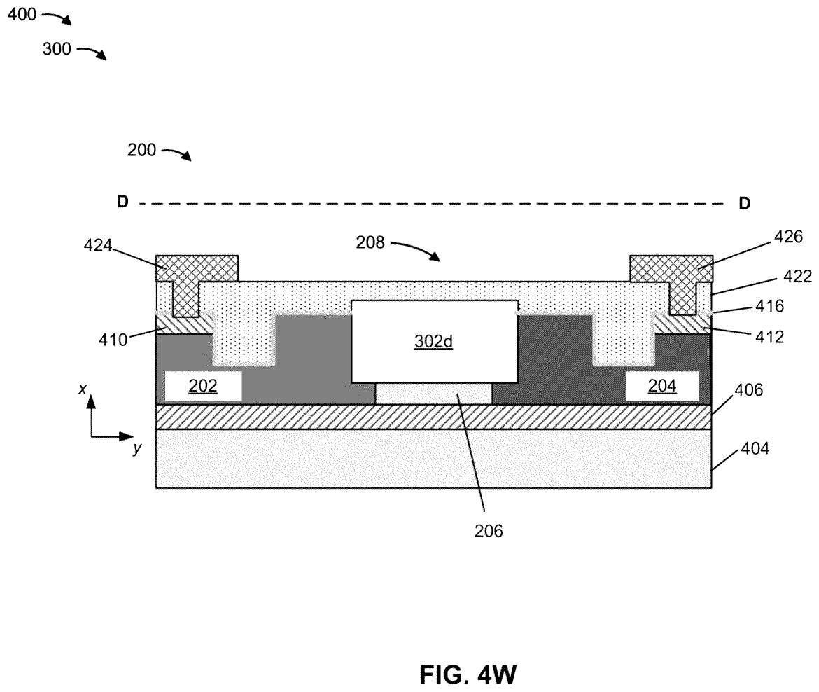

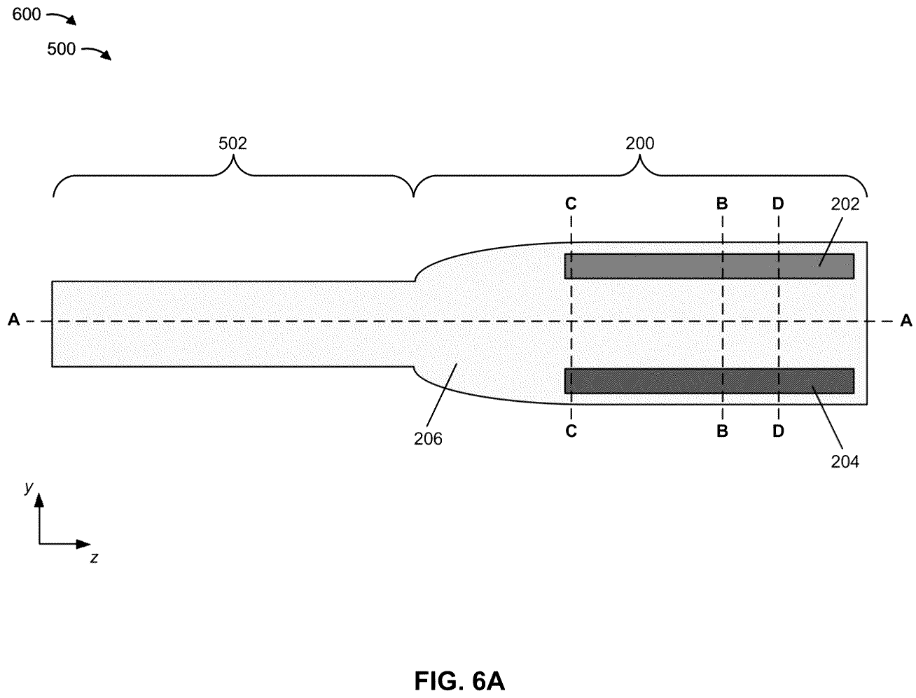

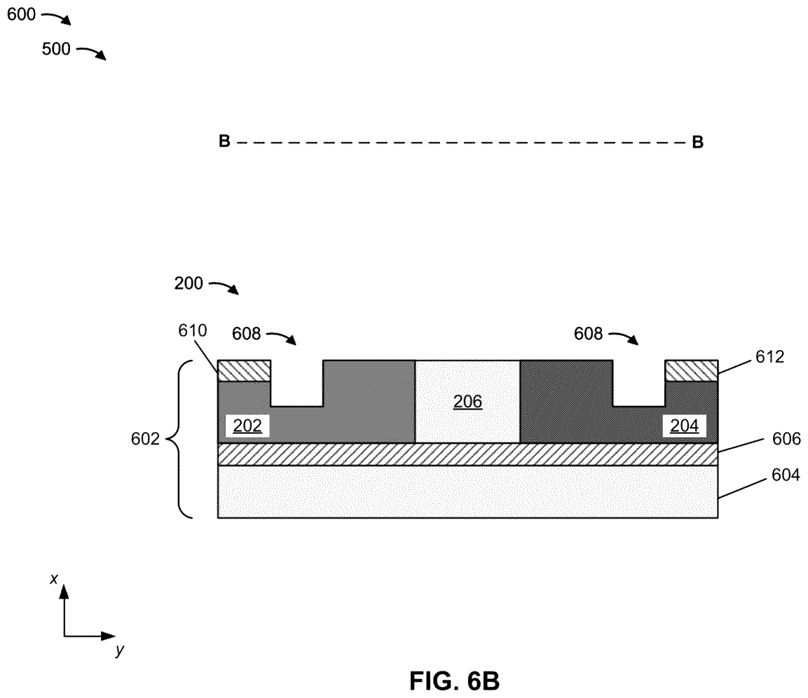

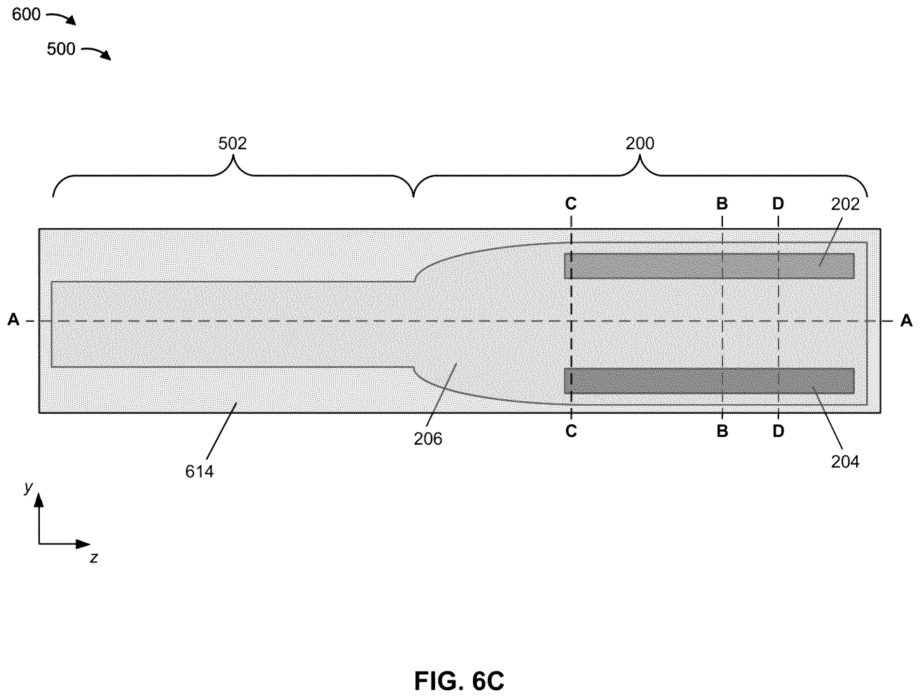

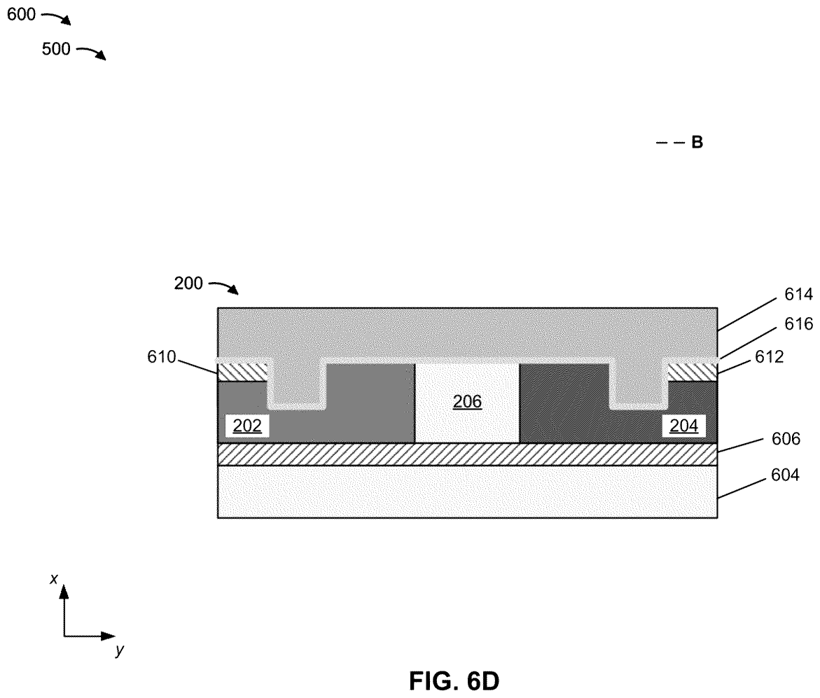

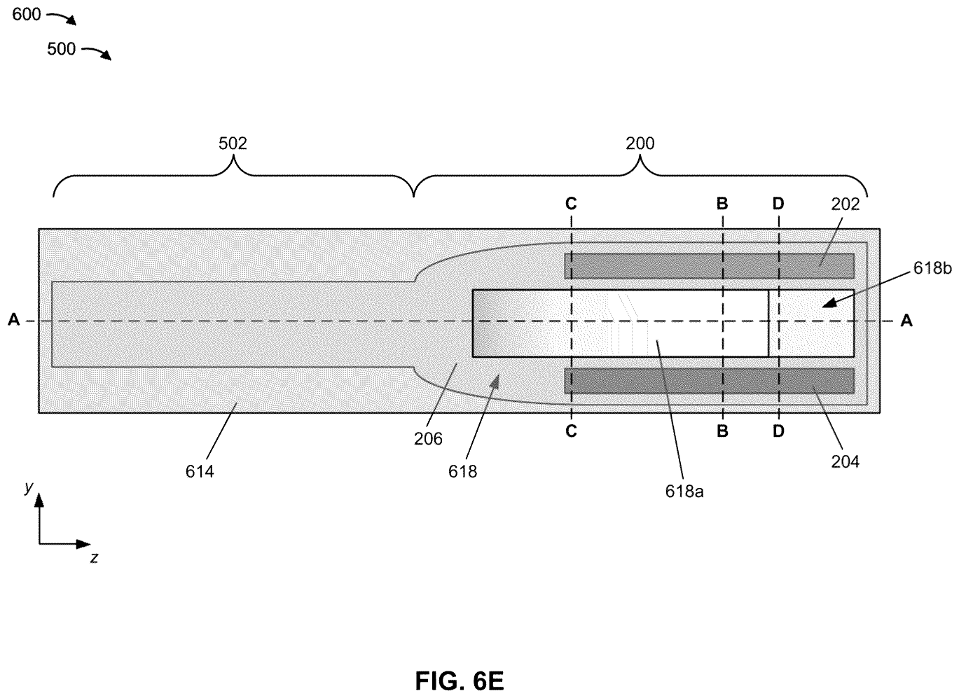

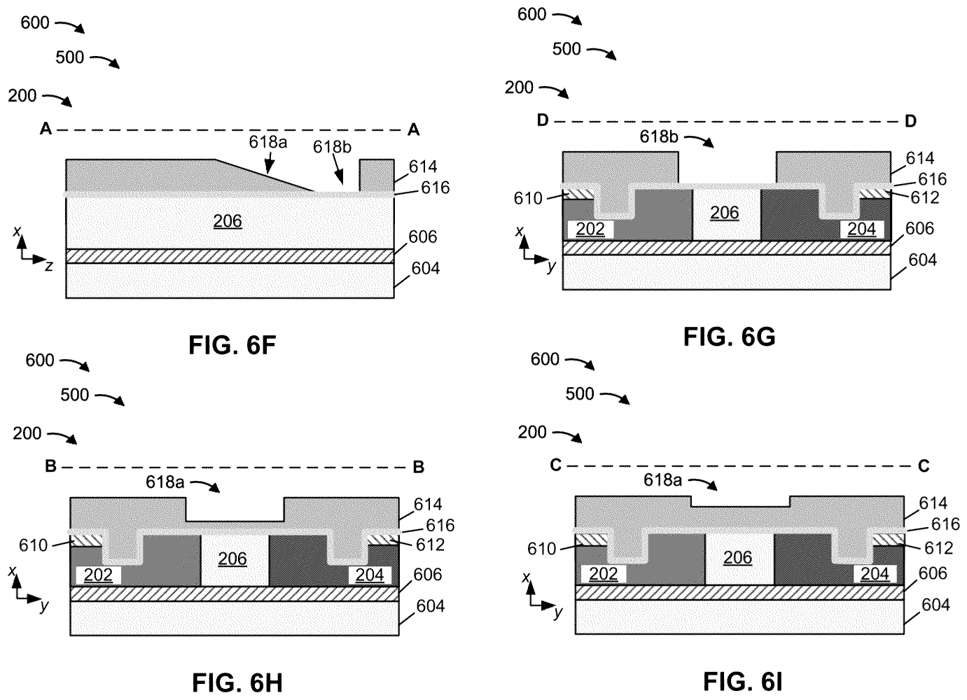

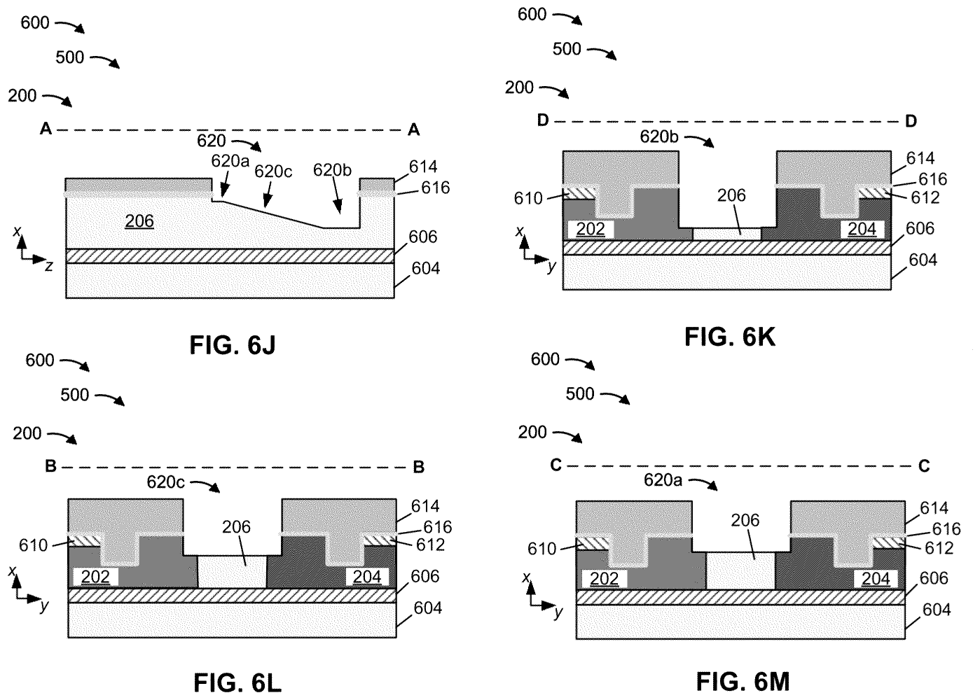

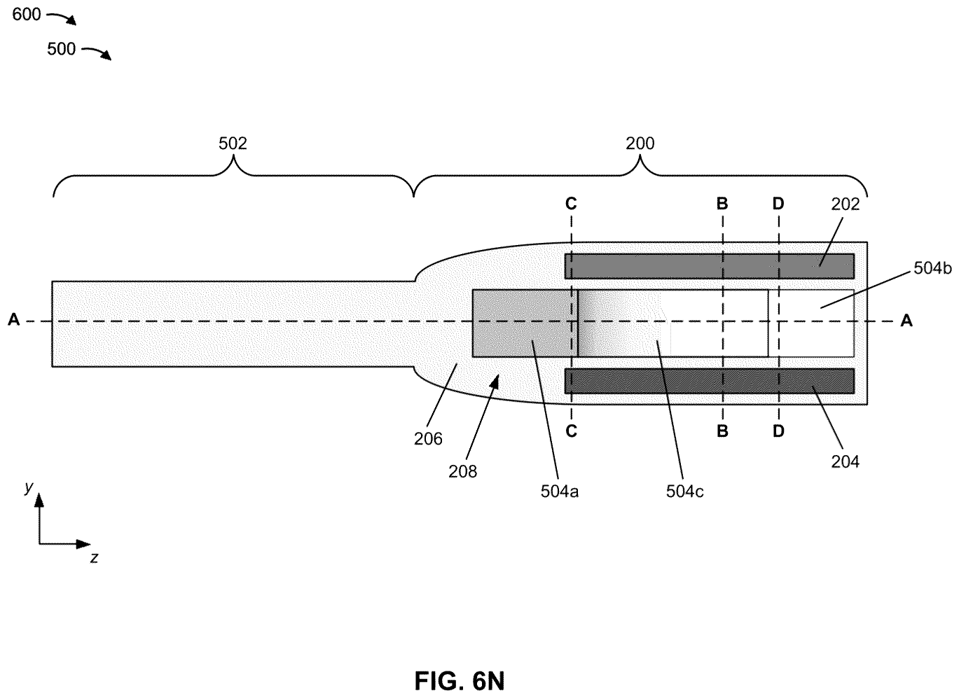

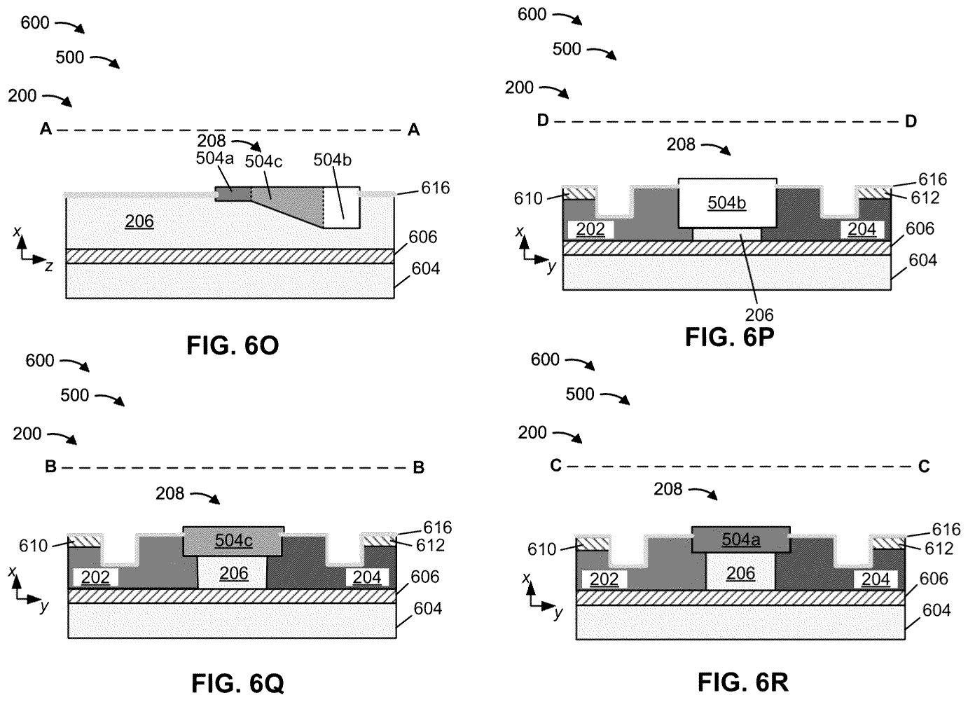

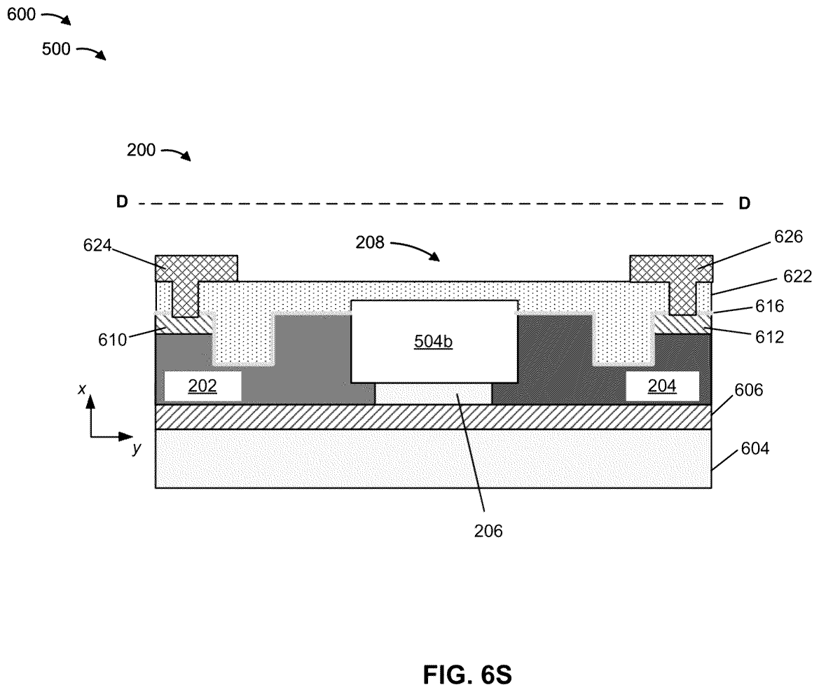

In some implementations, one or more of the semiconductor processing tools 102-114 and/or the wafer/die transport tool 116 may perform one or more semiconductor processing operations described herein. For example, one or more of the semiconductor processing tools 102-114 and/or the wafer/die transport tool 116 may form a masking layer over a substrate; may form a pattern in the masking layer, wherein the pattern includes a plurality of regions of the masking layer that have different heights; may etch the substrate in an etch operation based on the pattern to form a recess, in the substrate, having sections with different depths in the substrate; and/or may form an absorption region of a photodetector in the recess. In some implementations, one or more of the semiconductor processing tools 102-114 and/or the wafer/die transport tool 116 may perform one or more semiconductor processing operations described in connection with FIGS. 4A-4W, 6A-6S, and/or 10, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

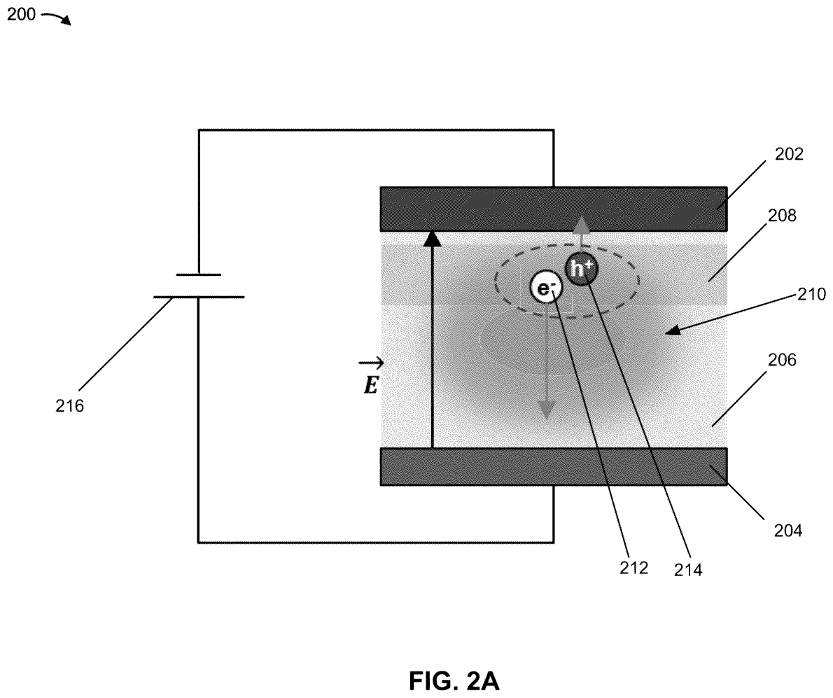

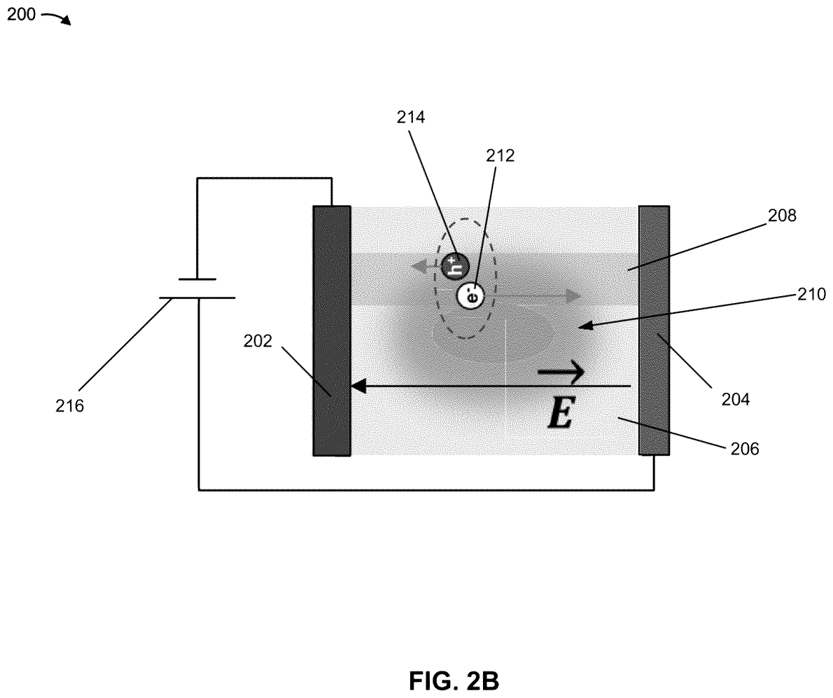

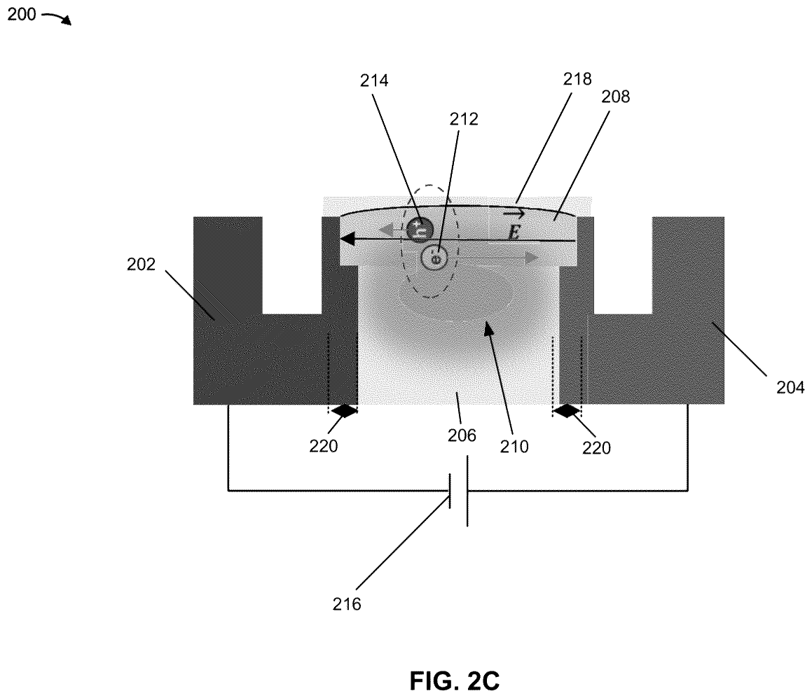

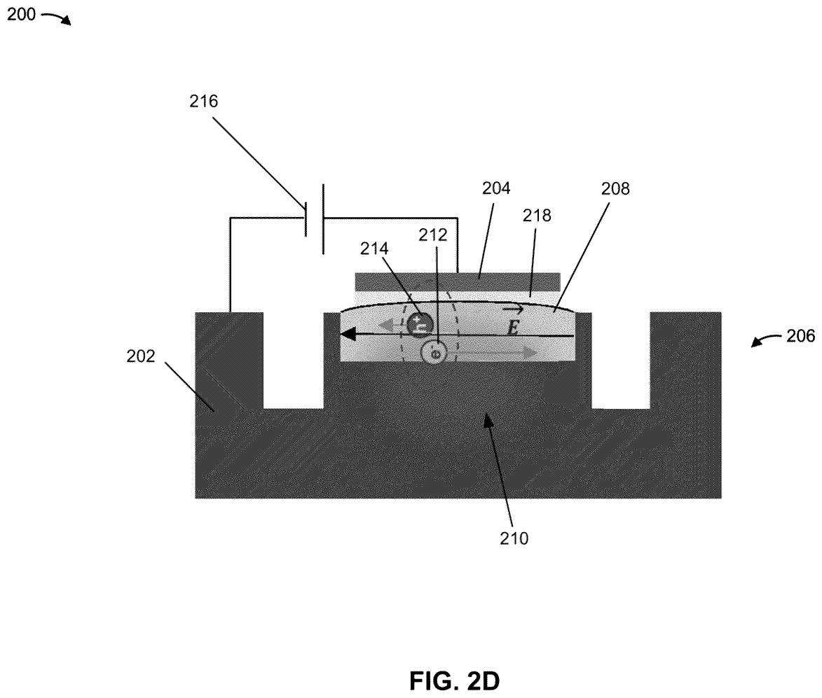

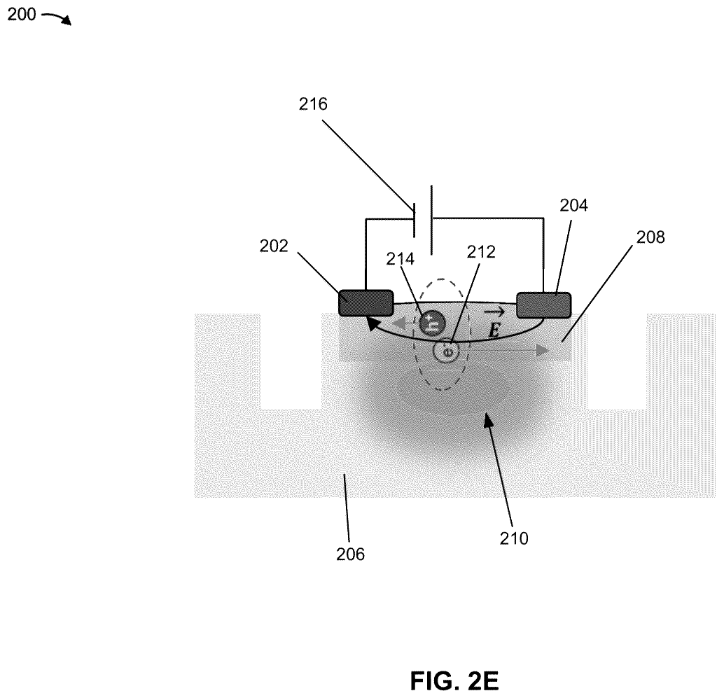

FIGS. 2A-2E are diagrams of example implementations of a photodetector 200 described herein. The photodetector 200 includes a semiconductor device that is configured to generate a current, a voltage, and/or another type of output based on absorbed photons of light. The photodetector 200 may be a standalone device or may be included in another device such as a photodetector device that includes a waveguide configured to direct incident light toward the photodetector 200.

As shown in an example implementation of the photodetector 200 in FIG. 2A, the photodetector 200 may include a p-type doped collection region 202 and an n-type doped collection region 204. The p-type doped collection region 202 may include a portion of a semiconductor substrate 206 that is doped with one or more p-type dopants such as boron (B) and/or indium (In), among other examples. The n-type doped collection region 204 may include a portion of the semiconductor substrate 206 that is doped with one or more p-type dopants such as phosphorous (P) and/or arsenic (As), among other examples. The semiconductor substrate 206 may be an intrinsic semiconductor substrate in that the semiconductor substrate 206 may include an undoped semiconductor material such as undoped silicon (Si), undoped germanium (Ge), undoped indium phosphate (InP), and/or undoped gallium arsenide (GaAs), among other examples.

An absorption region 208 of the photodetector 200 may be included in the semiconductor substrate 206 between the p-type doped collection region 202 and the n-type doped collection region 204. The absorption region 208 may be configured to absorb photons of incident light 210. The photons interact with electron-hole pairs in the absorption region 208.

The interaction causes electrons 212 and holes 214 to be separated and to migrate toward opposing collection regions through the semiconductor substrate 206, resulting in the generation of an electric field (e.g., a built-in electric field). The p-type doping of the p-type doped collection region 202 results in holes 214 being collected at the p-type doped collection region 202, whereas the n-type doping of the n-type doped collection region 204 results in electrons 212 being collected ts the n-type doped collection region 204.

The accumulation of holes 214 at the p-type doped collection region 202 and the accumulation of electrons 212 at the n-type doped collection region 204 causes a photocurrent to be generated at an output 216 of the photodetector 200. The magnitude of the current may be proportional to the amount of photons that is collected in the absorption region 208. Accordingly, the current that is generated at the output 216 may be an indication of the intensity of the incident light 210.

The absorption region 208 may include a semiconductor material. The semiconductor material of the absorption region 208 may be the same as the semiconductor material of the semiconductor substrate 206. Additionally and/or alternatively, the semiconductor material of the absorption region 208 and the semiconductor material of the semiconductor substrate 206 may be different semiconductor materials. Examples of semiconductor materials for the absorption region 208 include germanium (Ge), germanium tin (GeSn), silicon germanium (SiGe), indium gallium arsenide (InGaAs), and/or gallium arsenide (GaAs), among other examples.

In the example implementation of the photodetector 200 illustrated in FIG. 2A, the p-type doped collection region 202, the n-type doped collection region 204, and the absorption region 208 include elongated layers that extend in approximately parallel planes. The electric field generated in the photodetector 200 may be approximately parallel with the p-type doped collection region 202, the n-type doped collection region 204, and the absorption region 208, and approximately perpendicular with the direction of migration of the electrons 212 and holes 214.

In another example implementation of the photodetector 200 illustrated in FIG. 2B, the absorption region 208 is approximately perpendicular with the p-type doped collection region 202 and the n-type doped collection region 204. The electric field is approximately parallel with the absorption region 208 and approximately perpendicular with the p-type doped collection region 202 and the n-type doped collection region 204.

In another example implementation of the photodetector 200 illustrated in FIG. 2C, the p-type doped collection region 202 and the n-type doped collection region 204 may each include approximately U-shaped regions that are separated by the semiconductor substrate 206. The absorption region 208 may be between the p-type doped collection region 202 and the n-type doped collection region 204. An intrinsic semiconductor layer 218 may be included over the absorption region 208. The intrinsic semiconductor layer 218 and the profile of the top surface of the absorption region 208 may be tuned for various applications and/or use cases. In some implementations, the profile of the top surface of the absorption region 208 is substantially flat and planar. In some implementations, the profile of the top surface of the absorption region 208 is curved. Moreover, tuning regions 220 where the absorption region 208 overlaps the p-type doped collection region 202 and/or the absorption region 208 overlaps the n-type doped collection region 204 may provide further tuning of the photodetector 200 in that the amount of overlap in the tuning regions 220 may be selectable based on lithography alignment tolerance and/or to achieve one or more performance parameters for the photodetector 200.

In another example implementation of the photodetector 200 illustrated in FIG. 2D, the semiconductor substrate 206 is fully doped and corresponds to the p-type doped collection region 202. The absorption region 208 may be recessed in the p-type doped collection region 202, the intrinsic semiconductor layer 218 may be included over the absorption region 208, and the n-type doped collection region 204 may be included over the intrinsic semiconductor layer 218.

In another example implementation of the photodetector 200 illustrated in FIG. 2E, the absorption region 208 may be recessed in the semiconductor substrate 206, and the p-type doped collection region 202 and the n-type doped collection region 204 may be included on the absorption region 208.

As indicated above, FIGS. 2A-2E is provided as examples. Other examples may differ from what is described with regard to FIGS. 2A-2E.

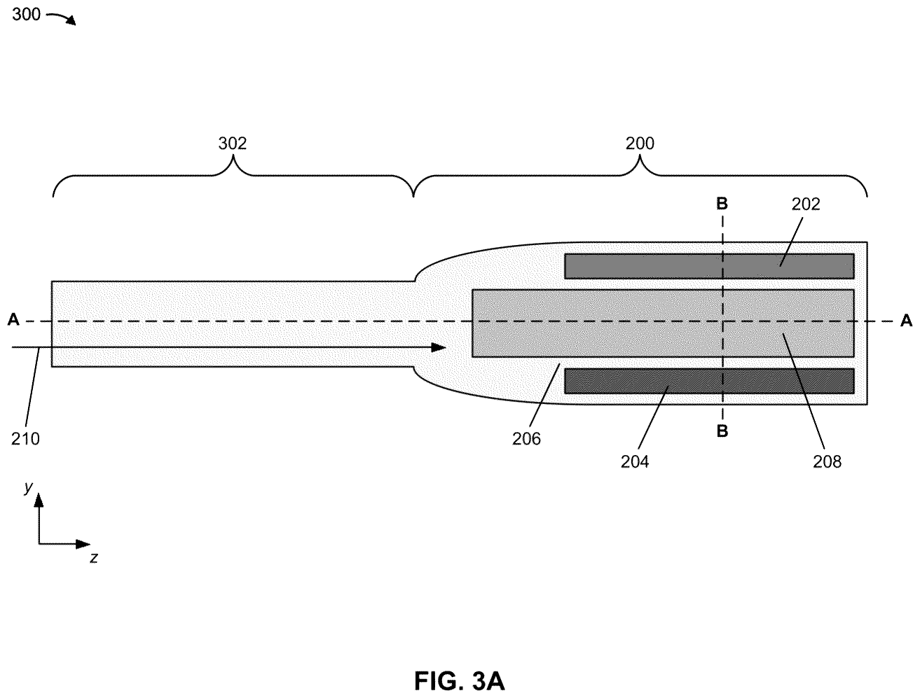

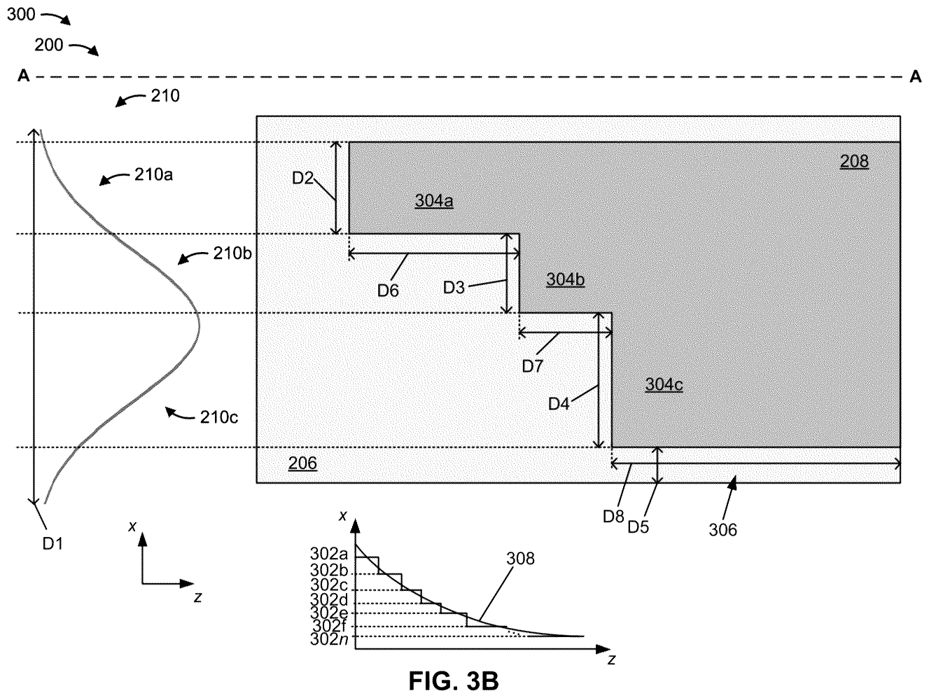

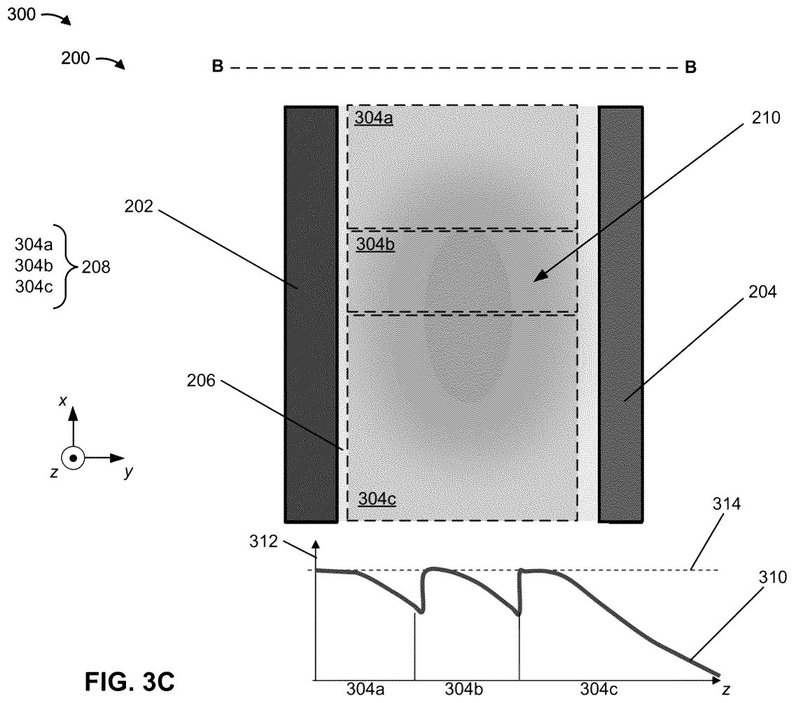

FIGS. 3A-3C are diagrams of an example implementation of a photodetector device 300 described herein. As shown in a top-down view of the photodetector device 300 in FIG. 3A, the photodetector device 300 may include a waveguide 302 and a photodetector 200 coupled with the waveguide 302. The waveguide 302 is configured to direct and/or otherwise provide incident light 210 to the photodetector 200. The waveguide 302 may include a portion of the semiconductor substrate 206, and may include an elongated structure that is configured to tightly or loosely confine the incident light 210 within the semiconductor substrate 206. The waveguide 302 may extend in a direction (e.g., z-direction) in the photodetector device 300 that is approximately parallel with the transmission direction of the incident light 210 (e.g., z-direction).

As further shown in FIG. 3A, the photodetector 200 may include the p-type doped collection region 202 in the semiconductor substrate 206, the n-type doped collection region 204 in the semiconductor substrate 206, and the absorption region 208 between the p-type doped collection region 202 and the n-type doped collection region 204 in the semiconductor substrate 206. The absorption region 208 may include an elongated region that is extends in the direction (e.g., z-direction) in the photodetector device 300 that is approximately parallel with the transmission direction of the incident light 210 (e.g., z-direction).

Various reference cross-sections illustrated in FIG. 3A are used in one or more figures described herein. Cross-section A-A is in a plane in the z-direction along the transmission direction of the incident light 210 and in a plane along the absorption region 208. Cross-section B-B is in a plane in a y-direction across the absorption region 208 that is approximately parallel with the transmission direction of the incident light 210.

FIG. 3B illustrates a cross-section of the photodetector 200 along the cross-section A-A in an x-z plane of the photodetector device 300. FIG. 3B illustrates a cross-sectional profile of the absorption region 208. As shown in FIG. 3B, the absorption region 208 includes a stepped cross-sectional profile in the z-direction (e.g., in the direction that is approximately parallel with a direction that the photodetector 200 is to receive the incident light 210 from the waveguide 302). The stepped cross-sectional profile includes a plurality of stepped sections 304a-304n along the z-direction, where the x-direction depth (or x-direction thickness) of the stepped sections 304a-304n increases along the z-direction. In some implementations, a regrowth region 306 is included under the absorption region 208 in the semiconductor substrate 206. The regrowth region 306 provides a substrate for epitaxial growth of the absorption region 208.

The stepped cross-sectional profile enables the absorption of photons of the incident light 210 to be distributed across different z-direction depths in the absorption region, thereby reducing the likelihood that any particular portion of the absorption region 208 reaches optical saturation. For example, a stepped section 304a of the absorption region 208 may absorb photons of a portion 210a of the incident light 210 at a first z-direction depth in the absorption region 208, a stepped section 304b of the absorption region 208 may absorb photons of a portion 210b of the incident light 210 at a second z-direction depth in the absorption region 208, a stepped section 304c of the absorption region 208 may absorb photons of a portion 210c of the incident light 210 at a third z-direction depth in the absorption region 208, and so on. The stepped cross-sectional profile of the absorption region 208 enables a gradient absorption profile 308 to be achieved for the absorption region 208, where absorption of photons of the incident light 210 is distributed along the z-direction depth in the absorption region 208 in an approximately uniform manner.

The quantity of the stepped sections 304a-304n, the size (e.g., the depth, the thickness, and/or the width) of the stepped sections 304a-304n, and/or the shape of the stepped sections 304a-304n may be based on a beam width (corresponding to dimension D1 in FIG. 3B) of the incident light 210, an x-direction thickness of the semiconductor substrate 206, a z-direction depth of the absorption region 208, and/or an optical intensity of the incident light 210, among other examples. Additionally and/or alternatively, the quantity of the stepped sections 304a-304n may be selected to achieve a particular gradient absorption profile 308 without unduly increasing manufacturing costs of the photodetector 200.

Each of the stepped sections 304a-304n may have an x-direction depth (or thickness) and a z-direction width (or depth). In some implementations, the top surface of the absorption region 208 may be substantially planar in the z-direction. Therefore, the x-direction depth of the stepped sections 304a-304n in the z-direction may correspond to the x-direction thickness of the stepped sections 304a-304n. For example, the stepped section 304a may have a dimension D2 corresponding to an x-direction depth (or thickness) of the stepped section 304a, the stepped section 304b may have a dimension D3 corresponding to an x-direction depth (or thickness) of the stepped section 304b, and the stepped section 304c may have a dimension D4 corresponding to an x-direction depth (or thickness) of the stepped section 304c. The dimension D4 may be selected to be at least the same size as or larger than the beam width (dimension D1) of the incident light 210 (e.g., D4≥D1) to provide photon absorption across the full beam width of the incident light. The dimension D3 may be selected to be approximately half of the beam width of the incident light 210 (e.g., D3≈x*D1, where x may be included in a range of approximately ⅓ to approximately ⅔), and the dimension D2 may be selected to be approximately one sixth of the beam width of the incident light 210 (e.g., D2≈y*D1, where y may be included in a range of approximately ⅛ to approximately ¼) to facilitate uniform distribution of photon absorption along the z-direction depth in the absorption region 208. However, other values for the dimensions D2-D4 are within the scope of the present disclosure. In some implementations, a ratio of D3 to D2 may be included in a range of approximately 2:1 to approximately 4:1. However, other values for the range are within the scope of the present disclosure. An x-direction thickness of the regrowth region 306 (corresponding to dimension D5) may be greater than approximately 5 nanometers, and may be selected to provide a sufficient lattice base for crystalline growth of the absorption region 208. However, other values are within the scope of the present disclosure.

In some implementations, the difference in x-direction depth (or x-direction thickness) between adjacent stepped sections of the stepped sections 304a-304n may be based on an optical confinement parameter associated with the absorption region 208. For example, the difference in x-direction depth (or x-direction thickness) between stepped sections 304a and 304b may be determined based on a product of the optical confinement that is to be achieved for the stepped section 304a and the z-direction width of the stepped section 304a (corresponding to dimension D6) and a product of the optical confinement that is to be achieved for the stepped section 304b and the z-direction width of the stepped section 304b (corresponding to dimension D7). The product of the optical confinement that is to be achieved for the stepped section 304b and the z-direction width of the stepped section 304b may be subtracted from the optical confinement that is to be achieved for the stepped section 304a and the z-direction width of the stepped section 304a to obtain the difference in x-direction depth (or x-direction thickness) between stepped sections 304a and 304b. In general, the z-direction widths of the stepped sections 304a-304n (e.g., the dimension D6, the dimension D7, a dimension D8, and so on) may be based on a resolution for the pattern that is used to form the stepped recess in which the absorption region 208 may be epitaxially grown.

FIG. 3C illustrates a cross-section of the photodetector 200 along the cross-section B-B in an x-y plane of the photodetector device 300. FIG. 3C illustrates a cross-sectional profile of the optical intensity of the incident light 210 on the absorption region 208. The optical intensity of the incident light 210 may generally be greatest near the center of the beam of the incident light 210 and may decrease radially outward from the center of the beam of the incident light 210. The stepped profile of the absorption region 208 in the z-direction enables the optical intensity of the incident light 210 to be distributed in the x-direction across the stepped sections 304a-304c along the x-direction thickness of the absorption region 208, where each of the stepped sections 304a-304c is located at a different z-direction depth in the absorption region 208 (e.g., looking into the page in FIG. 3C). This enables an optical power distribution profile 310 of optical power 312 (and/or photocurrent) that satisfies an optical power threshold 314 to be achieved in each of the stepped sections 304a-304c of the absorption region 208. The optical power threshold 314 may correspond to the optical power at which the absorption region 208 reaches optical saturation. Thus, the stepped sections 304a-304c of the absorption region 208 enable an optical power distribution profile 310 for the absorption region 208 that reduces the likelihood of optical saturation in the absorption region 208.

As indicated above, FIGS. 3A-3C are provided as an example. Other examples may differ from what is described with regard to FIGS. 3A-3C.

FIGS. 4A-4W are diagrams of an example implementation 400 of forming the photodetector device 300 described herein. In some implementations, one or more of the semiconductor processing operations described in connection with FIGS. 4A-4W may be performed using one or more of the semiconductor processing tools 102-116 described in connection with FIG. 1. In some implementations, one or more of the semiconductor processing operations described in connection with FIGS. 4A-4W may be performed using one or more other semiconductor processing tools.

As shown in a top-down view in FIG. 4A, a substrate 402 may be provided. One or more of the semiconductor processing operations described in connection with FIGS. 4A-4W may be performed in connection with the substrate 402. Moreover, one or more of the semiconductor processing operations described in connection with FIGS. 4A-4W may be illustrated in one or more of the cross-sections illustrated in FIG. 4A, such as the cross-section A-A, the cross-section B-B, a cross-section C-C in the y-direction, and/or a cross-section D-D in the y-direction.

As shown in an x-y cross-section view in FIG. 4B along cross-section B-B, the substrate 402 may include a silicon on insulator (SOI) substrate that includes a carrier substrate 404 (e.g., a silicon (Si) substrate and/or another type of carrier substrate), a dielectric layer 406 (e.g., a buried oxide or bottom oxide (BOX) layer and/or another type of insulator layer) over and/or on the carrier substrate 404, and a semiconductor substrate 206 (e.g., a silicon (Si) layer and/or another type of semiconductor layer) over and/or on the dielectric layer 406. Alternatively, the carrier substrate 404 may be provided as a semiconductor wafer, and a deposition tool 102 may be used to form the dielectric layer 406 over and/or on the carrier substrate 404, and a deposition tool 102 may be used to form the semiconductor substrate 206 over and/or on the dielectric layer 406. A deposition tool 102 may be used to form the dielectric layer 406 using a CVD technique, a PVD technique, an oxidation technique (e.g., a thermal oxidation technique), and/or another type of deposition technique. A deposition tool 102 may be used to form the semiconductor substrate 206 using a CVD technique, a PVD technique, an epitaxy technique, and/or another type of deposition technique.

As shown in a top-down view in FIG. 4C, portions of the substrate 402 may be removed to form a waveguide 302 and to define the region of the semiconductor substrate 206 for the photodetector 200. As shown in an x-y cross-section view in FIG. 4D along cross-section B-B, the removal of the portions of the substrate 402 may result in formation of recesses 408 in the semiconductor substrate 206.

In some implementations, a pattern in a photoresist layer is used to etch the semiconductor substrate 206 to form the recesses 408 to form a waveguide 302 and to define the region of the semiconductor substrate 206 for the photodetector 200. In these implementations, a deposition tool 102 may be used to form the photoresist layer on the semiconductor substrate 206. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the semiconductor substrate 206 based on the pattern to form the recesses 408 to form a waveguide 302 and to define the region of the semiconductor substrate 206 for the photodetector 200. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the semiconductor substrate 206 based on a pattern.

As further shown in FIG. 4D, the semiconductor substrate 206 may have one or more dimensions, such as a dimension D9, a dimension D10, a dimension D11, and/or a dimension D12, among other examples. The dimension D9 may correspond to a y-direction width of the recesses 408. The dimension D10 may correspond to an x-direction thickness of the semiconductor substrate 206 under the recesses 408. The dimension D11 may correspond to a y-direction width of the semiconductor substrate 206 between the recesses 408. The dimension D12 may correspond to an x-direction thickness of the semiconductor substrate 206 between the recesses 408. In some implementations, for single-mode operation of the photodetector 200, a ratio of the dimension D11 to the dimension D12 (D11:D12 or D11/D12) may be selected to satisfy:

$$\frac{D 11}{D 12} \leq 0.3 + \frac{r}{\sqrt{1 - {r}^{2}}}$$

where r may be greater than approximately 0.5 and may be selected as

$$r = \frac{D 10}{D 12}$$

However, other values for the ratio of the dimension D11 to the dimension D12 are within the scope of the present disclosure.

In some implementations, for single-mode operation of the photodetector 200, the dimension D9 may be selected to satisfy:

$$0.01 \times {P}_{total} \leq {\int }_{0}^{d} {P}_{opt} \cdot dx$$

In other words, the dimension D9 may be selected such that the total energy of optical power expansion (Pₜₒₜₐₗ) on the outer sides of the recesses 408 is less than approximately 0.01%. For multi-mode operation of the photodetector 200, the dimension D9 may be selected such that the total energy of optical power expansion (Pₜₒₜₐₗ) on the outer sides of the recesses 408 is less than approximately 0.05%. However, other values for the dimension D9 are within the scope of the present disclosure.

As shown in a top-down view in FIG. 4E, portions of the semiconductor substrate 206 in the photodetector 200 may be doped to form a p-type doped collection region 202 and an n-type doped collection region 204. For example, an ion implantation tool 114 may be used (e.g., using an ion implantation technique and/or another type of doping technique) to implant one or more portions of the semiconductor substrate 206 to dope the one or more portions of the semiconductor substrate 206 with p-type ions to form the p-type doped collection region 202. As another example, an ion implantation tool 114 may be used (e.g., using an ion implantation technique and/or another type of doping technique) to implant one or more portions of the semiconductor substrate 206 to dope the one or more portions of the semiconductor substrate 206 with n-type ions to form the n-type doped collection region 204.

As shown in an x-y cross-section view in FIG. 4F along cross-section B-B, a portion of the p-type doped collection region 202 may be further doped with p-type ions (e.g., using an ion implantation tool 114) to form a p-type contact region 410. A portion of the n-type doped collection region 204 may be further doped with n-type ions (e.g., using an ion implantation tool 114) to form an n-type contact region 412. The p-type dopant concentration in the p-type contact region 410 may be greater than the p-type dopant concentration in the p-type doped collection region 202. The n-type dopant concentration in the n-type contact region 412 may be greater than the n-type dopant concentration in the n-type doped collection region 204.

As shown in a top-down view in FIG. 4G, a masking layer 414 may be formed over the waveguide 302 and over the photodetector 200 of the photodetector device 300. In some implementations, the masking layer 414 may include a photoresist layer, and a deposition tool 102 may be used to deposit the masking layer 414 using a spin-coating technique and/or another type of deposition technique. In some implementations, the masking layer 414 includes a hard mask layer, and a deposition tool 102 may deposit the masking layer 414 using a CVD technique, a PVD technique, an ALD technique, and/or another suitable deposition technique.

As shown in an x-y cross-section view in FIG. 4H along cross-section B-B, the masking layer 414 may fill in the recesses 408 in the semiconductor substrate 206. Moreover, a hard mask layer 416 may be formed over the semiconductor substrate 206 prior to formation of the masking layer 414. The masking layer 414 may be formed on the hard mask layer 416. The hard mask layer 416 may include a silicon nitride (SiₓN_{y} such as Si₃N₄), a silicon oxynitride (SiON), and/or another suitable hard mask layer material. A deposition tool 102 may be used to deposit the hard mask layer 416 in a PVD operation, an ALD operation, a CVD operation, an oxidation operation, another type of deposition operation described in connection with FIG. 1, and/or another suitable deposition operation.

As shown in a top-down view in FIG. 4I, a stepped pattern 418 may be formed in the masking layer 414 over the photodetector 200. In particular, the stepped pattern 418 may be formed in the masking layer 414 between the p-type doped collection region 202 and the n-type doped collection region 204. The stepped pattern 418 may include a plurality of regions 418a-418d of the masking layer 414 having different x-direction heights. The different x-direction heights of the regions 418a-418d of the masking layer 414 enable the semiconductor substrate 206 to be etched to different depths to facilitate formation of a stepped profile for an absorption region 208 that is to be formed between the p-type doped collection region 202 and the n-type doped collection region 204.

FIGS. 4J-4M illustrate various cross-section views of the stepped pattern 418 formed in the masking layer 414. FIG. 4J illustrates an x-z cross-section view along cross-section A-A. FIG. 4K illustrates an x-y cross-section view along cross-section D-D. FIG. 4L illustrates an x-y cross-section view along cross-section B-B. FIG. 4M illustrates an x-y cross-section view along cross-section C-C.

As shown in FIG. 4J, the x-direction heights of the regions 418a-418d of the masking layer 414 may decrease along the z-direction (e.g., in a direction along a propagation path that is to be traversed by incident light 210 that is to be received by the photodetector 200) from the region 418a to the region 418d. As shown in FIG. 4K, in the region 418d, the masking layer 414 may be fully removed such that the region 418d includes an opening through the masking layer 414. As shown in FIGS. 4L and 4M, regions 418c and 418b respectively include remaining portions of the masking layer 414 over the semiconductor substrate 206.

In some implementations, the stepped pattern 418 may be formed by partially exposing (e.g., using an exposure tool 104) and/or partially developing (e.g., using a developer tool 106) the masking layer 414 in the regions 418a-418d such that the masking layer 414 is not fully removed from the regions 418a-418d except for the region 418d (where the masking layer 414 is fully removed). In some implementations, a stepped photomask is used to form the stepped pattern 418 in the masking layer 414.

FIGS. 4N-4Q illustrate various cross-section views of a stepped recess 420 that is formed in the semiconductor substrate 206 using the stepped pattern 418 formed in the masking layer 414. FIG. 4N illustrates an x-z cross-section view along cross-section A-A. FIG. 4O illustrates an x-y cross-section view along cross-section D-D. FIG. 4P illustrates an x-y cross-section view along cross-section B-B. FIG. 4Q illustrates an x-y cross-section view along cross-section C-C.

As shown in FIGS. 4N-4Q, sections 420a-420d of the stepped recess 420 may have different x-direction depths in the semiconductor substrate 206 as a result of etching the semiconductor substrate 206 (e.g., using an etch tool 108) based on the stepped pattern 418. In particular, the x-direction depths of the sections 420a-420d increase along the z-direction (e.g., in a direction along a propagation path that is to be traversed by incident light 210 that is to be received by the photodetector 200) from the section 420a to the section 420d. This may occur because the etchant that is used to etch the semiconductor substrate 206 based on the stepped pattern 418 is in contact with the semiconductor substrate 206 for the longest time duration in the region 418d of the stepped pattern 418 (e.g., because the masking layer 414 was fully removed in the region 418d), thereby resulting in the greatest etch depth in the semiconductor substrate 206 in the section 420d. The height of the masking layer 414 in the region 418c may be the next smallest, resulting in the second greatest etch depth in the semiconductor substrate 206 in the section 420c, and so on. The masking layer 414 is consumed during the etch operation to form the stepped recess 420 in the semiconductor substrate 206, which results in the semiconductor substrate 206 continuing to be further exposed in each of the regions 418c 4 418b 4 418a as the masking layer 414 is consumed. Thus, the etchant is in contact with the semiconductor substrate 206 for the longest time duration in the section 420d, and for the shortest time duration in the section 420a.

FIG. 4R illustrates a top-down view of the photodetector device 300 after formation of the absorption region 208 in the stepped recess 420. FIGS. 4S-4V illustrate various cross-section views of the stepped profile of the absorption region 208. FIG. 4S illustrates an x-z cross-section view along cross-section A-A. FIG. 4T illustrates an x-y cross-section view along cross-section D-D. FIG. 4U illustrates an x-y cross-section view along cross-section B-B. FIG. 4V illustrates an x-y cross-section view along cross-section C-C.

As shown in FIGS. 4R-4V, the absorption region 208 may be formed in the stepped recess 420. The stepped recess 420 results in the absorption region 208 including sections 304a-304c having x-direction depths (or x-direction thicknesses) along the z-direction. In some implementations, a deposition tool 102 is used to epitaxially grow the absorption region 208 in the stepped recess 420. In some implementations, a deposition tool 102 is used to deposit the absorption region 208 in the stepped recess 420 in a PVD operation, an ALD operation, a CVD operation, an epitaxy operation, an oxidation operation, another type of deposition operation described in connection with FIG. 1, and/or another suitable deposition operation. In some implementations, a planarization tool 110 planarizes the absorption region 208 after the absorption region 208 is deposited.

As shown in an x-y cross-section view in FIG. 4W along cross-section D-D, a dielectric layer 422 may be formed over the p-type doped collection region 202, over the n-type doped collection region 204, and/or over the absorption region 208. A deposition tool 102 may be used to deposit the dielectric layer 422 in a PVD operation, an ALD operation, a CVD operation, an epitaxy operation, an oxidation operation, another type of deposition operation described in connection with FIG. 1, and/or another suitable deposition operation. In some implementations, a planarization tool 110 may be used to planarize the dielectric layer 422 after the dielectric layer 422 is deposited.

As further shown in FIG. 4W, contacts 424 and 426 may be formed. The contact 424 may be formed such that the contact 424 is electrically coupled and/or physically coupled with the p-type contact region 410 and/or the p-type doped collection region 202. The contact 426 may be formed such that the contact 426 is electrically coupled and/or physically coupled with the n-type contact region 412 and/or the n-type doped collection region 204. An etch tool 108 may be used to remove portions of the dielectric layer 422 to expose the p-type contact region 410 and the n-type contact region 412 through the dielectric layer 422. A deposition tool 102 may deposit the contact 424 on the p-type contact region 410 and may deposit the contact 426 on the n-type contact region 412 through recesses formed through the dielectric layer 422 by removing the portions of the dielectric layer 422.

A deposition tool 102 and/or a plating tool 112 may be used to deposit the contacts 424 and 426 in a CVD operation, a PVD operation, an ALD operation, an electroplating operation, another deposition operation described above in connection with FIG. 1, and/or another suitable deposition operation. In some implementations, a seed layer is first deposited, and the contacts 424 and/or 426 are deposited on the seed layer. In some implementations, a planarization tool 110 may be used to planarize the contacts 424 and/or 426 after the contacts 424 and/or 426 are deposited.

As indicated above, FIGS. 4A-4W are provided as an example. Other examples may differ from what is described with regard to FIGS. 4A-4W.

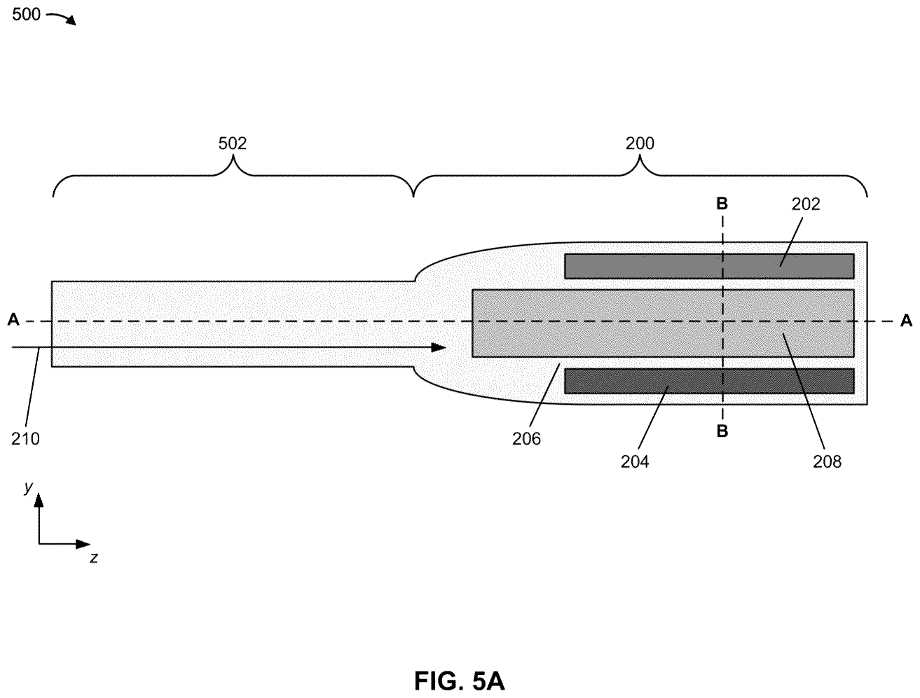

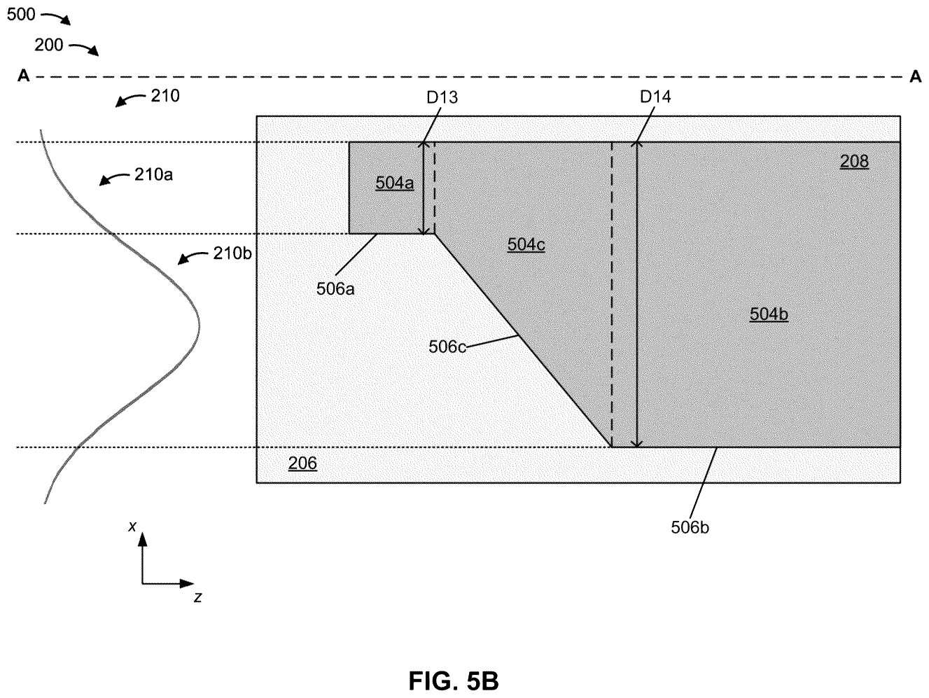

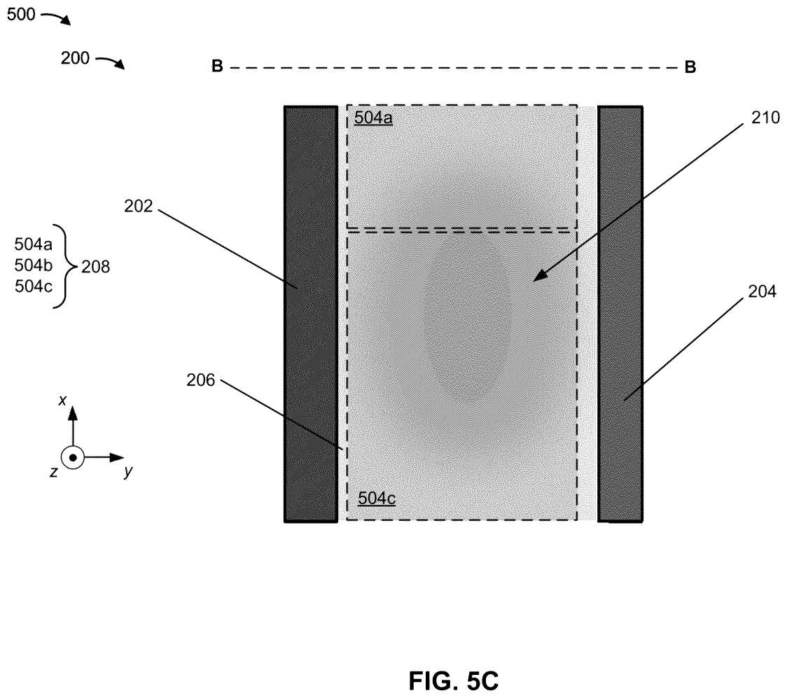

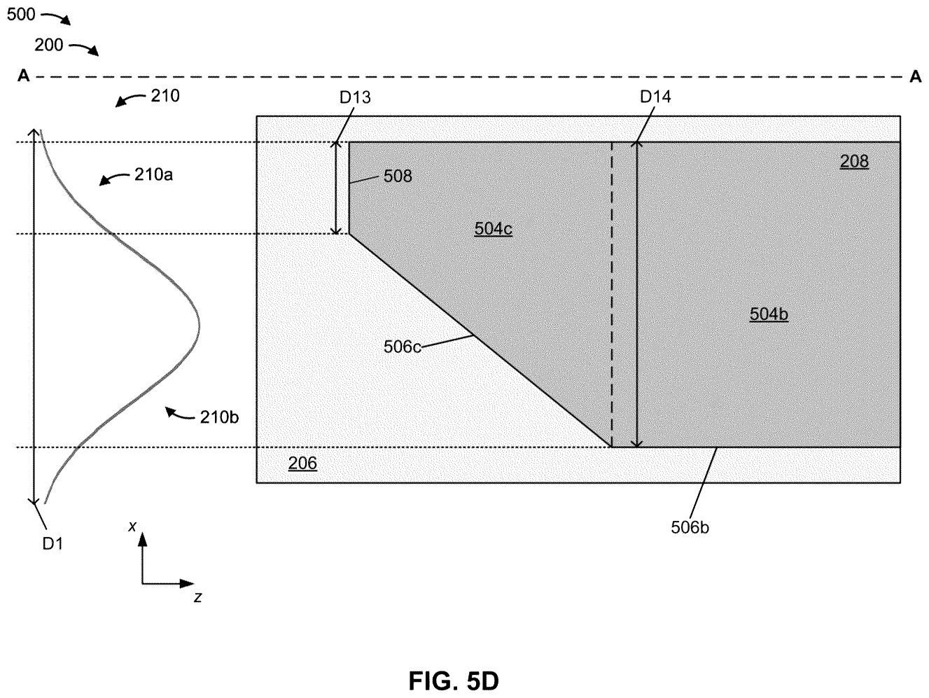

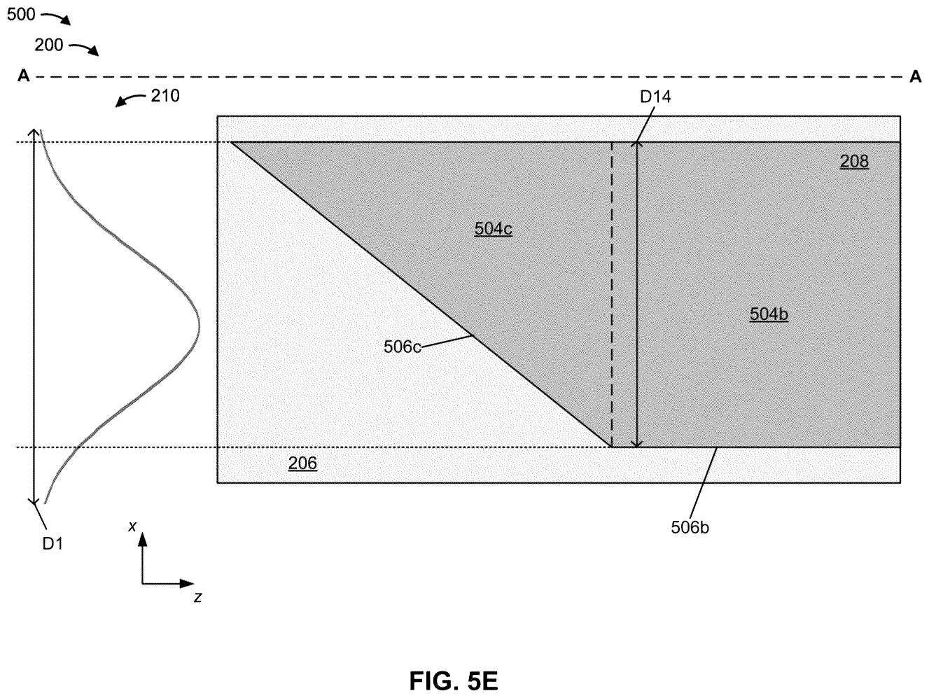

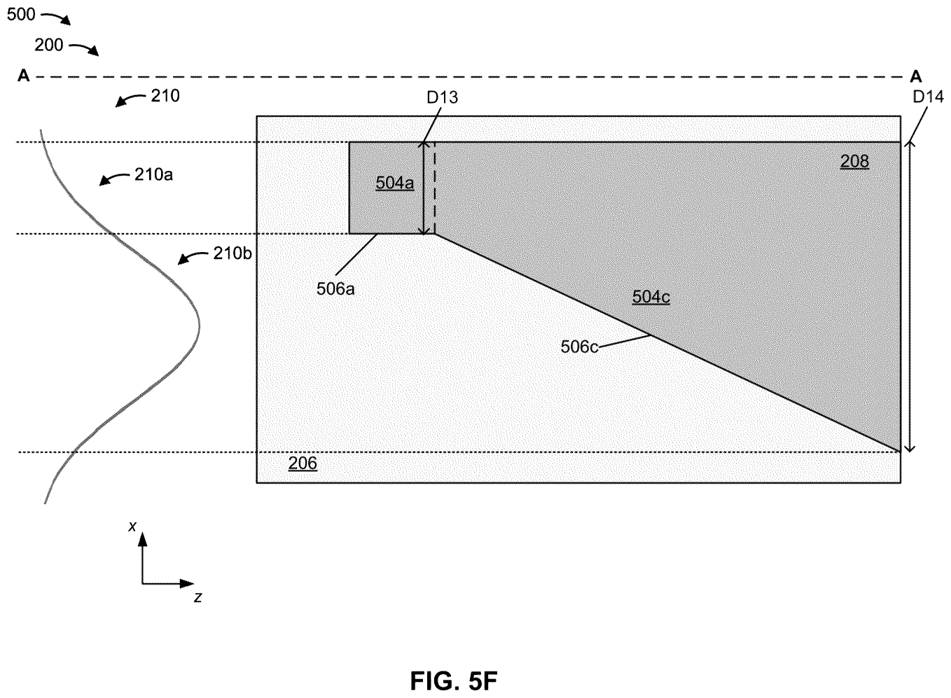

FIGS. 5A-5F are diagrams of example implementations of a photodetector device 500 described herein. As shown in FIGS. 5A-5F, the example implementations of the photodetector device 500 illustrated in FIGS. 5A-5F may include a similar combination and/or arrangement of elements as the example implementation of the photodetector device 300 illustrated in FIGS. 3A-3C. For example, the example implementations of the photodetector device 500 illustrated in FIGS. 5A-5F may include a waveguide 502, a photodetector 200 coupled with the waveguide 502, a p-type doped collection region 202 in the semiconductor substrate 206, an n-type doped collection region 204 in the semiconductor substrate 206, and an absorption region 208 between the p-type doped collection region 202 and the n-type doped collection region 204 in the semiconductor substrate 206. However, as shown in FIGS. 5B-5F, the absorption region 208 in the example implementations of the photodetector device 500 illustrated in FIGS. 5A-5F includes a tapered (or angled) cross-sectional profile in the z-direction (e.g., in the direction that is approximately parallel with a direction that the photodetector 200 is to receive the incident light 210 from the waveguide 502). The tapered cross-sectional profile for the absorption region 208 may further increase the uniformity of photon absorption distribution along the z-direction depth in the absorption region 208. However, the stepped cross-sectional profile for the absorption region 208 in the photodetector device 300 may be less costly and less complex to manufacture.

As shown in an example implementation of the tapered profile of the absorption region 208 in FIG. 5B, the absorption region 208 may include a flat-bottomed section 504a, a flat-bottomed section 504b, and a sloped section 504c between the flat-bottomed sections 504a and 504b. The flat-bottomed section 504a includes an approximately flat bottom surface 506a that is approximately parallel with the z-direction and is approximately parallel with an approximately flat bottom surface 506b of the flat-bottomed section 504b. The sloped section 504c includes a sloped bottom surface 506c that transitions between an x-direction depth of the flat bottom surface 506a (corresponding to a dimension D13) of the flat-bottomed section 504a and an x-direction depth of the flat bottom surface 506b (corresponding to a dimension D14) of the flat-bottomed section 504b. The x-direction depth of the flat bottom surface 506b may be greater than the x-direction depth of the flat bottom surface 506a, and therefore the sloped bottom surface 506c of the sloped section 504c may be angled downward such that the x-direction depth of the sloped section 504c increases from the flat-bottomed section 504a to the flat-bottomed section 504b.

The flat-bottomed section 504a may be configured to receive and absorb photons of a portion 210a of incident light 210, and the sloped section 504c may be configured to receive and absorb photons of a portion 210b of incident light 210. The tapered cross-sectional profile enables the absorption of photons of the incident light 210 to be distributed across a more gradual and granular distribution of z-direction depths in the absorption region, thereby further reducing the likelihood that any particular portion of the absorption region 208 reaches optical saturation. The angle of the sloped bottom surface 506c of the sloped section 504c may be selected to achieve a particular gradient absorption profile and/or to achieve a particular optical confinement profile for the photodetector 200.

FIG. 5C illustrates a cross-section of the photodetector 200 along the cross-section B-B in an x-y plane of the photodetector device 500. The tapered profile of the absorption region 208 in the z-direction enables the optical intensity of the incident light 210 to be distributed in the x-direction across the flat-bottomed section 504a and the sloped section 504c along the x-direction thickness of the absorption region 208, where each of the flat-bottomed section 504a and the sloped section 504c is located at a different z-direction depth in the absorption region 208 (e.g., looking into the page in FIG. 5C).

FIG. 5D illustrates another example implementation of the photodetector device 500 in which the flat-bottomed section 504a is omitted. In this implementation, a flat portion 508 of the sloped section 504c is configured to receive and absorb photons of the portion 210a of the incident light 210. The sloped bottom surface 506c of the sloped section 504c transitions between an x-direction depth of the flat portion 508 (corresponding to a dimension D13) and the x-direction depth of the flat bottom surface 506b (corresponding to a dimension D14) of the flat-bottomed section 504b.

FIG. 5E illustrates another example implementation of the photodetector device 500 in which the flat-bottomed section 504a and flat portion 508 are omitted. In this implementation, the sloped section 504c is configured to receive and absorb photons of the entire beam width of the incident light 210. The x-direction depth of the sloped bottom surface 506c gradually increases toward the x-direction depth of the flat bottom surface 506b (corresponding to a dimension D14) of the flat-bottomed section 504b.

FIG. 5F illustrates another example implementation of the photodetector device 500 in which the flat-bottomed section 504b is omitted. In this implementation, the sloped bottom surface 506c of the sloped section 504c transitions between an x-direction depth of the flat-bottomed section 504a (corresponding to a dimension D13) and an x-direction depth of the sloped bottom surface 506c on an opposing side of the sloped section 504c (corresponding to a dimension D14).

As indicated above, FIGS. 5A-5F are provided as examples. Other examples may differ from what is described with regard to FIGS. 5A-5F.

FIGS. 6A-6S are diagrams of an example implementation 600 of forming the photodetector device 500 described herein. In some implementations, one or more of the semiconductor processing operations described in connection with FIGS. 6A-6W may be performed using one or more of the semiconductor processing tools 102-116 described in connection with FIG. 1. In some implementations, one or more of the semiconductor processing operations described in connection with FIGS. 6A-6S may be performed using one or more other semiconductor processing tools.

As shown in FIGS. 6A and 6B, similar semiconductor processing operations as those described in connection with FIGS. 4A-4F may be performed to form a p-type doped collection region 202 in a semiconductor substrate 206 of a substrate 602 above a carrier substrate 604 and above a dielectric layer 606, to form an n-type doped collection region 204 in the semiconductor substrate 206, to form recesses 608 in the semiconductor substrate 206, to form a p-type contact region 610 in the p-type doped collection region 202, and/or to form an n-type contact region 612 in the n-type doped collection region 204.

As shown in a top-down view in FIG. 6C, a masking layer 614 may be formed over the waveguide 502 and over the photodetector 200 of the photodetector device 500. In some implementations, the masking layer 614 may include a photoresist layer, and a deposition tool 102 may be used to deposit the masking layer 614 using a spin-coating technique and/or another type of deposition technique. In some implementations, the masking layer 614 includes a hard mask layer, and a deposition tool 102 may deposit the masking layer 614 using a CVD technique, a PVD technique, an ALD technique, and/or another suitable deposition technique.

As shown in an x-y cross-section view in FIG. 6D along cross-section B-B, the masking layer 614 may fill in the recesses 608 in the semiconductor substrate 206. Moreover, a hard mask layer 616 may be formed over the semiconductor substrate 206 prior to formation of the masking layer 614. The masking layer 614 may be formed on the hard mask layer 616. The hard mask layer 616 may include a silicon nitride (SiₓN_{y} such as Si₃N₄), a silicon oxynitride (SiON), and/or another suitable hard mask layer material. A deposition tool 102 may be used to deposit the hard mask layer 616 in a PVD operation, an ALD operation, a CVD operation, an oxidation operation, another type of deposition operation described in connection with FIG. 1, and/or another suitable deposition operation.

As shown in a top-down view in FIG. 6E, a gradient pattern 618 may be formed in the masking layer 614 over the photodetector 200. In particular, the gradient pattern 618 may be formed in the masking layer 614 between the p-type doped collection region 202 and the n-type doped collection region 204. The gradient pattern 618 may include a plurality of regions 618a and 618b of the masking layer 614 having different x-direction heights. The different x-direction heights of the regions 618a and 618b of the masking layer 614 enable the semiconductor substrate 206 to be etched to different depths to facilitate formation of a tapered profile for an absorption region 208 that is to be formed between the p-type doped collection region 202 and the n-type doped collection region 204.

FIGS. 6F-6I illustrate various cross-section views of the gradient pattern 618 formed in the masking layer 614. FIG. 6F illustrates an x-z cross-section view along cross-section A-A. FIG. 6G illustrates an x-y cross-section view along cross-section D-D. FIG. 6H illustrates an x-y cross-section view along cross-section B-B. FIG. 6I illustrates an x-y cross-section view along cross-section C-C.

As shown in FIG. 6F, the x-direction heights of the regions 618a and 618b of the masking layer 614 may decrease along the z-direction (e.g., in a direction along a propagation path that is to be traversed by incident light 210 that is to be received by the photodetector 200) from the region 618a to the region 618d. Moreover, the region 618a may have an angled top surface resulting in a decrease in x-direction height within the region 618a. As shown in FIG. 6G, in the region 618d, the masking layer 614 may be fully removed such that the region 618d includes an opening through the masking layer 614. As shown in FIGS. 6H and 6I, the region 618a includes remaining portions of the masking layer 614 over the semiconductor substrate 206.

In some implementations, the gradient pattern 618 may be formed by using a gradient photomask to progressive increase the exposure (e.g., using an exposure tool 104) of the masking layer 614 in the regions 618a and 618d such that the masking layer 614 is not fully removed from the region 618a, and such that the masking layer 614 is fully removed from the region 618d.

FIGS. 6J-6M illustrate various cross-section views of an angled recess 620 that is formed in the semiconductor substrate 206 using the gradient pattern 618 formed in the masking layer 614. FIG. 6J illustrates an x-z cross-section view along cross-section A-A. FIG. 6K illustrates an x-y cross-section view along cross-section D-D. FIG. 6L illustrates an x-y cross-section view along cross-section B-B. FIG. 6M illustrates an x-y cross-section view along cross-section C-C.

As shown in FIGS. 6J-6M, sections 620a-620d of the angled recess 620 may have different x-direction depths in the semiconductor substrate 206 as a result of etching the semiconductor substrate 206 (e.g., using an etch tool 108) based on the gradient pattern 618. In particular, the x-direction depths of the sections 620a-620d increase along the z-direction (e.g., in a direction along a propagation path that is to be traversed by incident light 210 that is to be received by the photodetector 200) from the section 620a (e.g., a flat section) to the section 620d (e.g., another flat section). The x-direction depth in the section 620c (e.g., an angled section) may gradually increase from the section 620a to the section 620b. This may occur because the etchant that is used to etch the semiconductor substrate 206 based on the gradient pattern 618 is in contact with the semiconductor substrate 206 for the longest time duration in the region 618d of the gradient pattern 618 (e.g., because the masking layer 614 was fully removed in the region 618d), thereby resulting in the greatest etch depth in the semiconductor substrate 206 in the section 620d. The angled top surface of the region 618a of the gradient pattern 618 results in the masking layer 614 being gradually etched away in the region 618a, resulting in the angled bottom surface of the section 620c.

FIG. 6N illustrates a top-down view of the photodetector device 500 after formation of the absorption region 208 in the angled recess 620. FIGS. 6O-6R illustrate various cross-section views of the stepped profile of the absorption region 208. FIG. 6O illustrates an x-z cross-section view along cross-section A-A. FIG. 6P illustrates an x-y cross-section view along cross-section D-D. FIG. 6Q illustrates an x-y cross-section view along cross-section B-B. FIG. 6R illustrates an x-y cross-section view along cross-section C-C.

As shown in FIGS. 6N-6R, the absorption region 208 may be formed in the angled recess 620. The angled recess 620 results in the absorption region 208 including sections 504a-504c having x-direction depths (or x-direction thicknesses) along the z-direction, with the sloped section 504c having a sloped bottom surface. In some implementations, a deposition tool 102 is used to epitaxially grow the absorption region 208 in the angled recess 620. In some implementations, a deposition tool 102 is used to deposit the absorption region 208 in the angled recess 620 in a PVD operation, an ALD operation, a CVD operation, an epitaxy operation, an oxidation operation, another type of deposition operation described in connection with FIG. 1, and/or another suitable deposition operation. In some implementations, a planarization tool 110 planarizes the absorption region 208 after the absorption region 208 is deposited.

As shown in an x-y cross-section view in FIG. 6S along cross-section D-D, a dielectric layer 622 may be formed over the p-type doped collection region 202, over the n-type doped collection region 204, and/or over the absorption region 208. A deposition tool 102 may be used to deposit the dielectric layer 622 in a PVD operation, an ALD operation, a CVD operation, an epitaxy operation, an oxidation operation, another type of deposition operation described in connection with FIG. 1, and/or another suitable deposition operation. In some implementations, a planarization tool 110 may be used to planarize the dielectric layer 622 after the dielectric layer 622 is deposited.

As further shown in FIG. 6S, contacts 624 and 626 may be formed. The contact 624 may be formed such that the contact 624 is electrically coupled and/or physically coupled with the p-type contact region 610 and/or the p-type doped collection region 202. The contact 626 may be formed such that the contact 626 is electrically coupled and/or physically coupled with the n-type contact region 612 and/or the n-type doped collection region 204. An etch tool 108 may be used to remove portions of the dielectric layer 622 to expose the p-type contact region 610 and the n-type contact region 612 through the dielectric layer 622. A deposition tool 102 may deposit the contact 624 on the p-type contact region 610 and may deposit the contact 626 on the n-type contact region 612 through recesses formed through the dielectric layer 622 by removing the portions of the dielectric layer 622.

A deposition tool 102 and/or a plating tool 112 may be used to deposit the contacts 624 and 626 in a CVD operation, a PVD operation, an ALD operation, an electroplating operation, another deposition operation described above in connection with FIG. 1, and/or another suitable deposition operation. In some implementations, a seed layer is first deposited, and the contacts 624 and/or 626 are deposited on the seed layer. In some implementations, a planarization tool 110 may be used to planarize the contacts 624 and/or 626 after the contacts 624 and/or 626 are deposited.

As indicated above, FIGS. 6A-6S are provided as an example. Other examples may differ from what is described with regard to FIGS. 6A-6S.

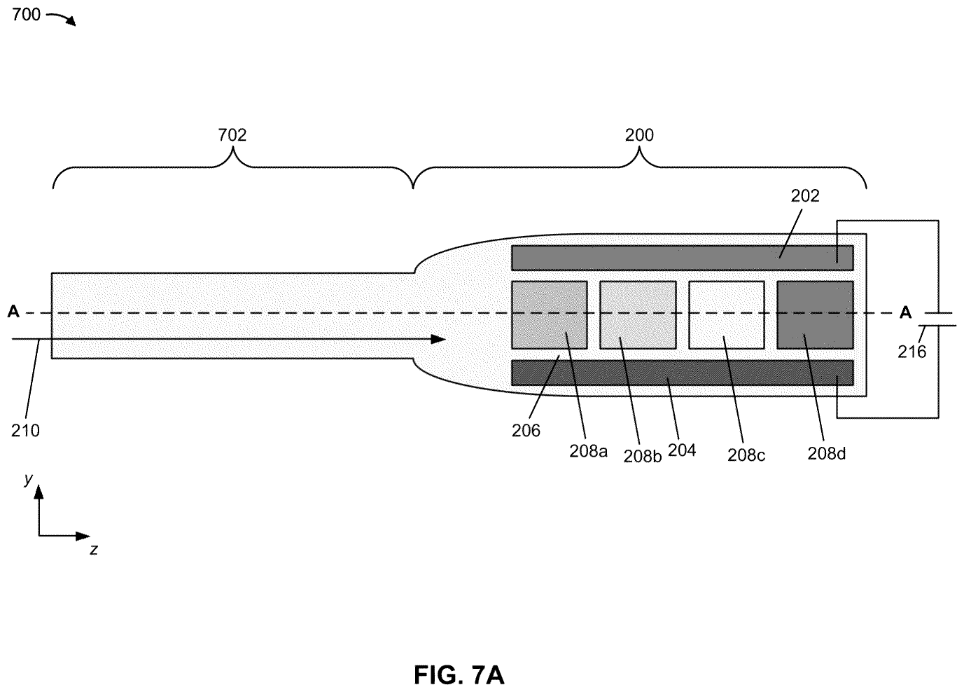

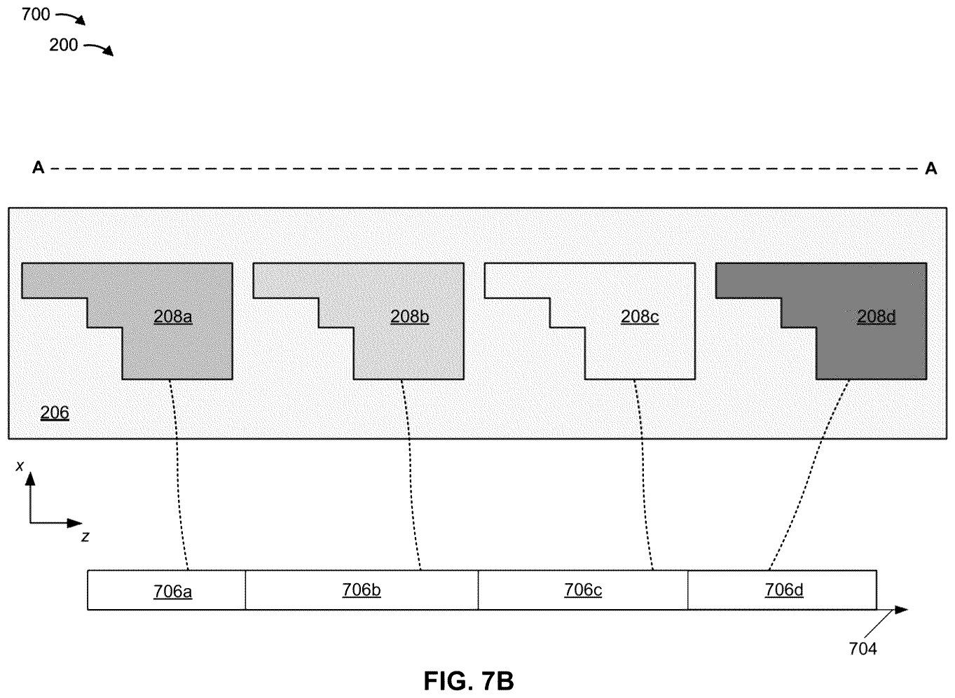

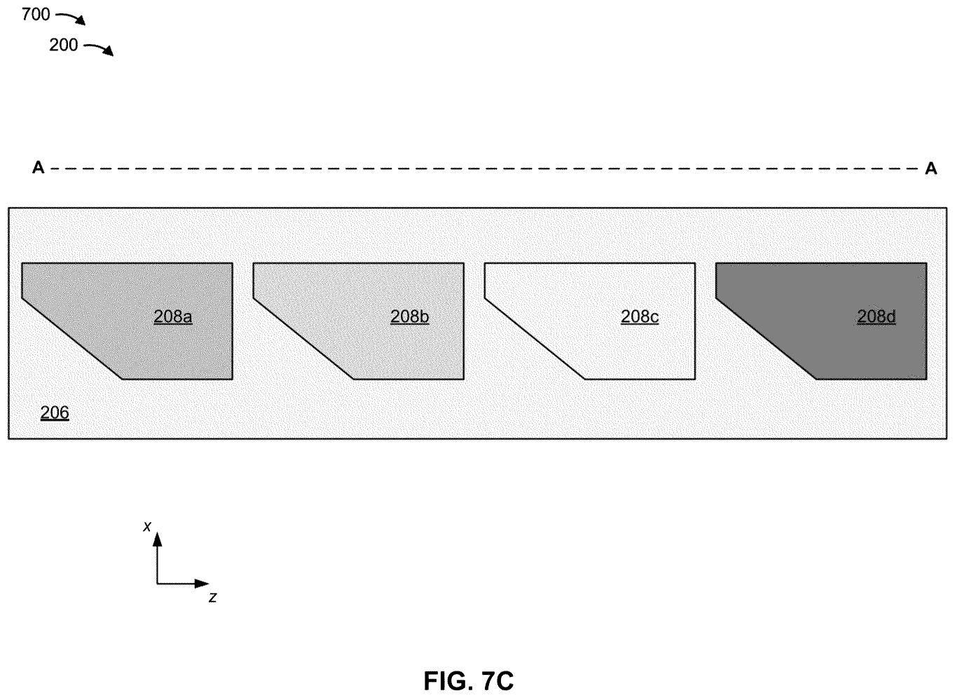

FIGS. 7A-7C are diagrams of example implementations of a photodetector device 700 described herein. As shown in FIGS. 7A-7C, the example implementations of the photodetector device 700 illustrated in FIGS. 7A-7C may include a similar combination and/or arrangement of elements as the example implementation of the photodetector device 300 illustrated in FIGS. 3A-3C. For example, the example implementations of the photodetector device 700 illustrated in FIGS. 7A-7C may include a waveguide 702, a photodetector 200 coupled with the waveguide 702, a p-type doped collection region 202 in the semiconductor substrate 206, an n-type doped collection region 204 in the semiconductor substrate 206, and an absorption region 208 between the p-type doped collection region 202 and the n-type doped collection region 204 in the semiconductor substrate 206. However, as shown in FIGS. 7A-7C, the photodetector 200 includes a plurality of absorption regions 208a-208d in the example implementations of the photodetector device 700 illustrated in FIGS. 7A-7C. The absorption regions 208a-208d may each be coupled with the p-type doped collection region 202 and the n-type doped collection region 204 such that a single photocurrent is generated and provided to an output 216.

As shown in FIG. 7B, each of the absorption regions 208a-208d may be configured to absorb photons of respective wavelength ranges of the incident light 210. For example, in an electromagnetic spectrum 704, the absorption region 208a may be configured to absorb photons in a wavelength range 706a, the absorption region 208b may be configured to absorb photons in a wavelength range 706b, the absorption region 208c may be configured to absorb photons in a wavelength range 706c, and/or the absorption region 208d may be configured to absorb photons in a wavelength range 706d. This may enable the optical bandwidth of the photodetector 200 to be increased. Moreover, this may further reduce the likelihood of optical saturation in the photodetector 200 in that the optical power of the incident light 210 is distributed across a plurality of absorption regions 208a-208d.

In some implementations, one or more of the wavelength ranges 706a-706d may correspond to different colors in the visible light spectrum on the electromagnetic spectrum 704. For example, the wavelength range 706a may correspond to blue light, the wavelength range 706b may correspond to green light, and so on. In some implementations, a subset of the wavelength ranges 706a-706d may correspond to different colors in the visible light spectrum, and another subset of the wavelength ranges 706a-706d may correspond to one or more non-visible light spectrum ranges. For example, one or more of the wavelength ranges 706a-706d may correspond to an infrared wavelength range and/or a near infrared wavelength range.

In some implementations, two or more of the absorption regions 208a-208d may include the same semiconductor material and/or the same combinations of semiconductor materials. In some implementations, two or more of the absorption regions 208a-208d may include different semiconductor materials and/or different combinations of semiconductor materials. For example, an absorption region 208a may include silicon (Si), an absorption region 208b may include germanium (Ge), and so on. As another example, an absorption region 208a may include a silicon germanium (SiₓGeₓ₋₁) compound where x is 0.1, an absorption region 208b may include a silicon germanium (SiₓGeₓ₋₁) compound where x is 0.8, and so on. This enables the quantum efficiencies for the absorption regions 208a-208d to be tuned for the particular wavelength ranges 706a-706d that the absorption regions 208a-208d are to absorb.

As further shown in FIG. 7B, the absorption regions 208a-208d may be formed to include stepped profiles (e.g., similar to the absorption region 208 in FIG. 3B). As shown in FIG. 7C, the absorption regions 208a-208d may be formed to include tapered profiles (e.g., similar to the absorption regions 208 in FIGS. 5B, and/or 5D-5F). In some implementations, the absorption regions 208a-208d may be formed such that a subset of the absorption regions 208a-208d include stepped profiles and another subset of the absorption regions 208a-208d include tapered profiles.

As indicated above, FIGS. 7A-7C is provided as an example. Other examples may differ from what is described with regard to FIGS. 7A-7C.

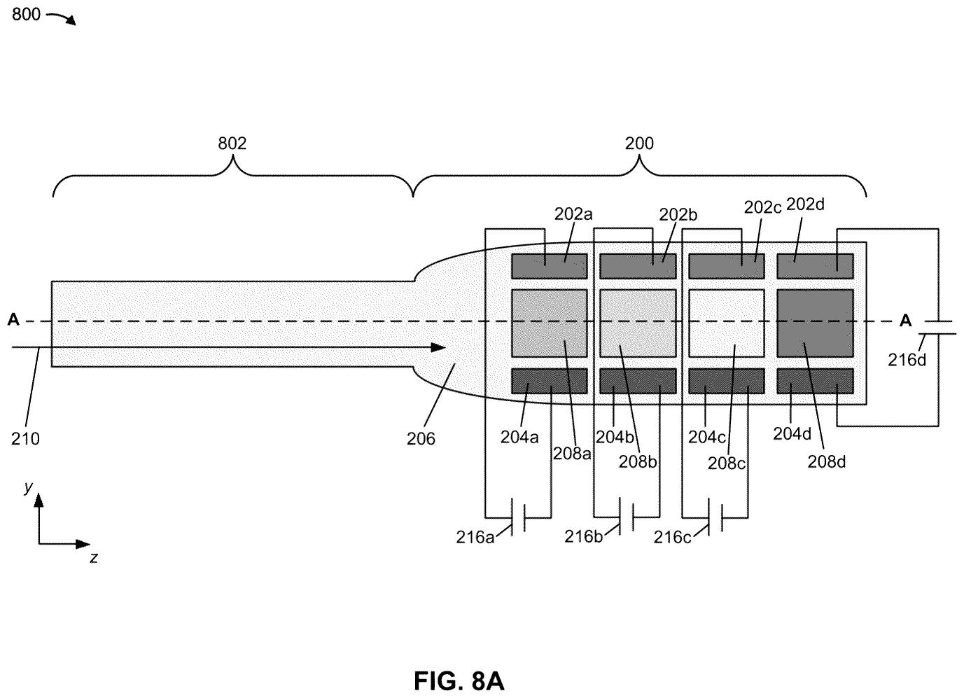

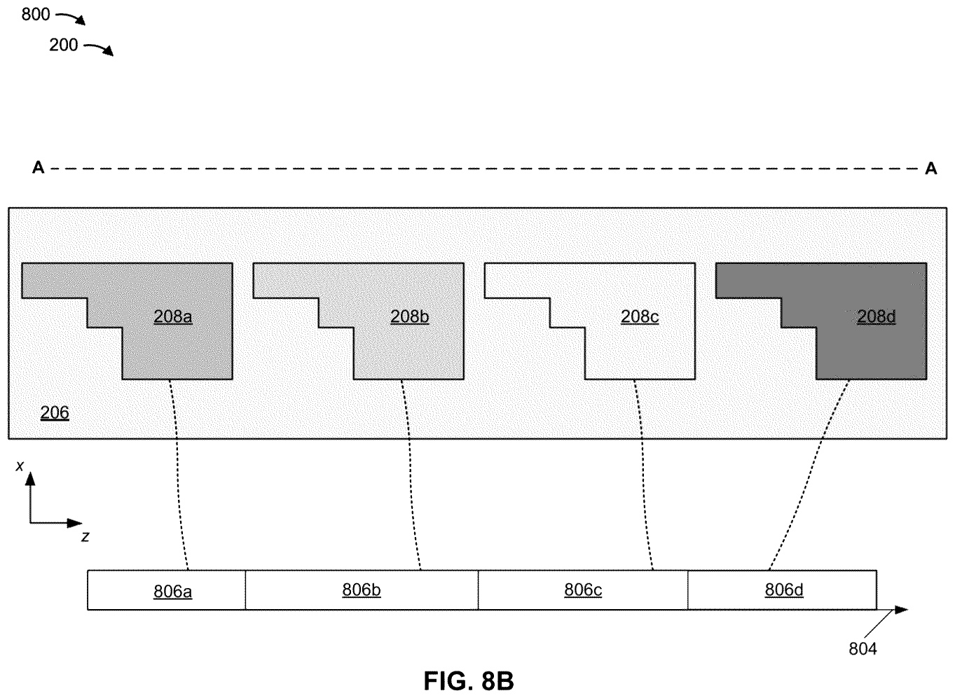

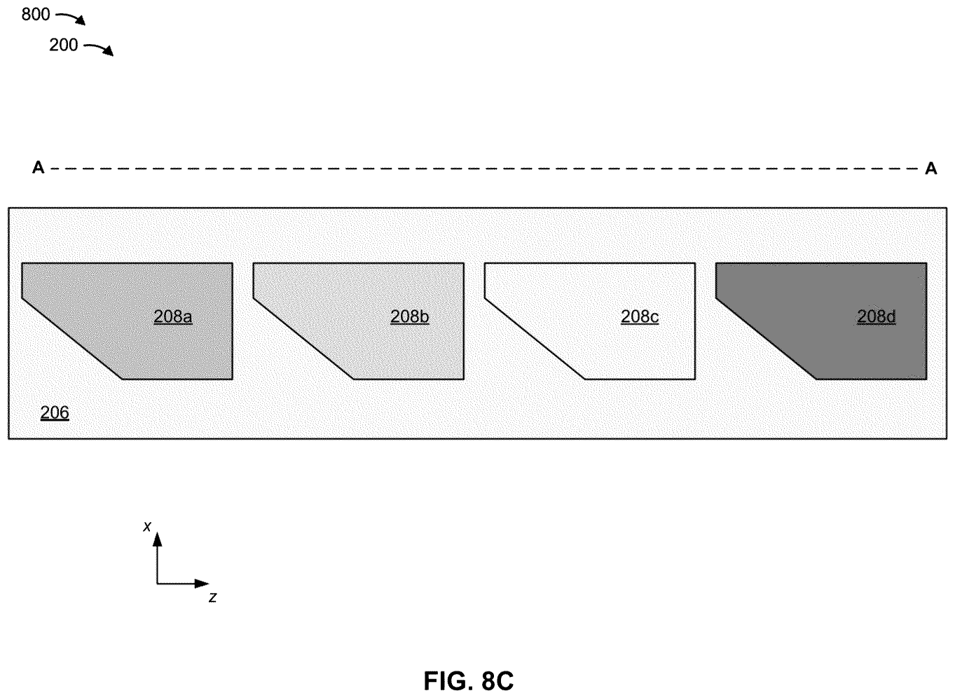

FIGS. 8A-8C are diagrams of example implementations of a photodetector device 800 described herein. As shown in FIGS. 8A-8C, the example implementations of the photodetector device 800 illustrated in FIGS. 8A-8C may include a similar combination and/or arrangement of elements as the example implementation of the photodetector device 300 illustrated in FIGS. 3A-3C. For example, the example implementations of the photodetector device 800 illustrated in FIGS. 8A-8C may include a waveguide 802, a photodetector 200 coupled with the waveguide 802, a p-type doped collection region 202 in the semiconductor substrate 206, an n-type doped collection region 204 in the semiconductor substrate 206, and an absorption region 208 between the p-type doped collection region 202 and the n-type doped collection region 204 in the semiconductor substrate 206. However, as shown in FIGS. 8A-8C, the photodetector 200 includes a plurality of absorption regions 208a-208d in the example implementations of the photodetector device 800 illustrated in FIGS. 8A-8C. The absorption regions 208a-208d may each be coupled with respective p-type doped collection regions 202a-202d and to respective n-type doped collection regions 204a-204d such that respective photocurrents are generated and provided to respective outputs 216a-216d. This enables the photodetector 200 to function as a wavelength separator, a wavelength splitter, a wavelength filter, and/or a wavelength sensor, among other examples.

As shown in FIG. 8B, each of the absorption regions 208a-208d may be configured to absorb photons of respective wavelength ranges of the incident light 210. For example, in an electromagnetic spectrum 804, the absorption region 208a may be configured to absorb photons in a wavelength range 806a, the absorption region 208b may be configured to absorb photons in a wavelength range 806b, the absorption region 208c may be configured to absorb photons in a wavelength range 806c, and/or the absorption region 208d may be configured to absorb photons in a wavelength range 806d. This may enable the optical bandwidth of the photodetector 200 to be increased. Moreover, this may further reduce the likelihood of optical saturation in the photodetector 200 in that the optical power of the incident light 210 is distributed across a plurality of absorption regions 208a-208d.

In some implementations, one or more of the wavelength ranges 806a-806d may correspond to different colors in the visible light spectrum on the electromagnetic spectrum 804. For example, the wavelength range 806a may correspond to blue light, the wavelength range 806b may correspond to green light, and so on. In some implementations, a subset of the wavelength ranges 806a-806d may correspond to different colors in the visible light spectrum, and another subset of the wavelength ranges 806a-806d may correspond to one or more non-visible light spectrum ranges. For example, one or more of the wavelength ranges 806a-806d may correspond to an infrared wavelength range and/or a near infrared wavelength range.

In some implementations, two or more of the absorption regions 208a-208d may include the same semiconductor material and/or the same combinations of semiconductor materials. In some implementations, two or more of the absorption regions 208a-208d may include different semiconductor materials and/or different combinations of semiconductor materials. For example, an absorption region 208a may include silicon (Si), an absorption region 208b may include germanium (Ge), and so on. As another example, an absorption region 208a may include a silicon germanium (SiₓGeₓ₋₁) compound where x is 0.1, an absorption region 208b may include a silicon germanium (SiₓGeₓ₋₁) compound where x is 0.8, and so on. This enables the quantum efficiencies for the absorption regions 208a-208d to be tuned for the particular wavelength ranges 806a-806d that the absorption regions 208a-208d are to absorb.

As further shown in FIG. 8B, the absorption regions 208a-208d may be formed to include stepped profiles (e.g., similar to the absorption region 208 in FIG. 3B). As shown in FIG. 8C, the absorption regions 208a-208d may be formed to include tapered profiles (e.g., similar to the absorption regions 208 in FIGS. 5B, and/or 5D-5F). In some implementations, the absorption regions 208a-208d may be formed such that a subset of the absorption regions 208a-208d include stepped profiles and another subset of the absorption regions 208a-208d include tapered profiles.

As indicated above, FIGS. 8A-8C is provided as an example. Other examples may differ from what is described with regard to FIGS. 8A-8C.

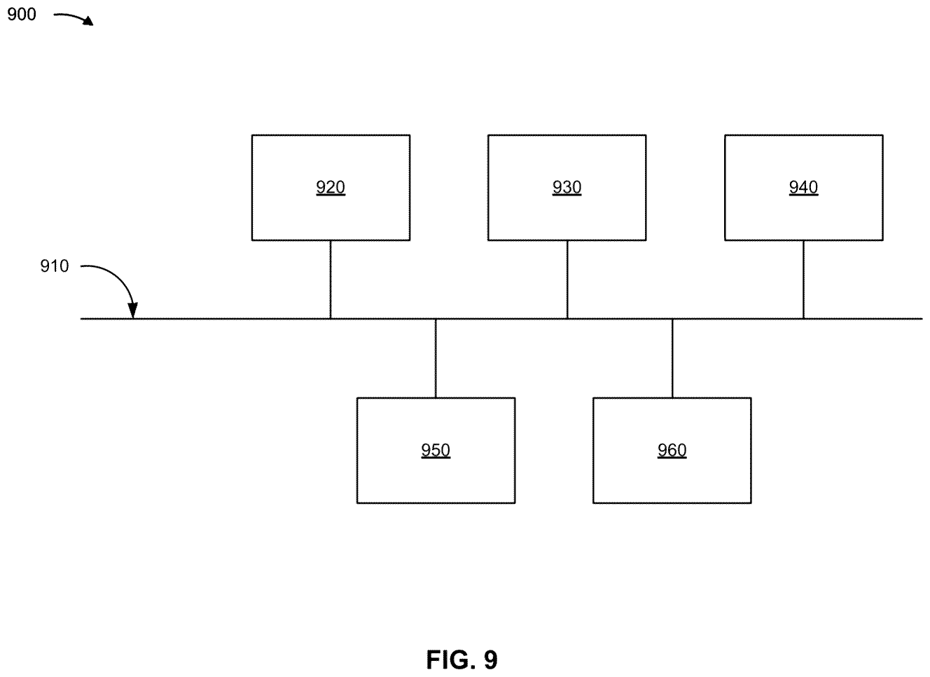

FIG. 9 is a diagram of example components of a device 900 described herein. In some implementations, one or more of the semiconductor processing tools 102-114 and/or the wafer/die transport tool 116 may include one or more devices 900 and/or one or more components of the device 900. As shown in FIG. 9, the device 900 may include a bus 910, a processor 920, a memory 930, an input component 940, an output component 950, and/or a communication component 960.

The bus 910 may include one or more components that enable wired and/or wireless communication among the components of the device 900. The bus 910 may couple together two or more components of FIG. 9, such as via operative coupling, communicative coupling, electronic coupling, and/or electric coupling. For example, the bus 910 may include an electrical connection (e.g., a wire, a trace, and/or a lead) and/or a wireless bus. The processor 920 may include a central processing unit, a graphics processing unit, a microprocessor, a controller, a microcontroller, a digital signal processor, a field-programmable gate array, an application-specific integrated circuit, and/or another type of processing component. The processor 920 may be implemented in hardware, firmware, or a combination of hardware and software. In some implementations, the processor 920 may include one or more processors capable of being programmed to perform one or more operations or processes described elsewhere herein.

The memory 930 may include volatile and/or nonvolatile memory. For example, the memory 930 may include random access memory (RAM), read only memory (ROM), a hard disk drive, and/or another type of memory (e.g., a flash memory, a magnetic memory, and/or an optical memory). The memory 930 may include internal memory (e.g., RAM, ROM, or a hard disk drive) and/or removable memory (e.g., removable via a universal serial bus connection). The memory 930 may be a non-transitory computer-readable medium. The memory 930 may store information, one or more instructions, and/or software (e.g., one or more software applications) related to the operation of the device 900. In some implementations, the memory 930 may include one or more memories that are coupled (e.g., communicatively coupled) to one or more processors (e.g., processor 920), such as via the bus 910. Communicative coupling between a processor 920 and a memory 930 may enable the processor 920 to read and/or process information stored in the memory 930 and/or to store information in the memory 930.

The input component 940 may enable the device 900 to receive input, such as user input and/or sensed input. For example, the input component 940 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 950 may enable the device 900 to provide output, such as via a display, a speaker, and/or a light-emitting diode. The communication component 960 may enable the device 900 to communicate with other devices via a wired connection and/or a wireless connection. For example, the communication component 960 may include a receiver, a transmitter, a transceiver, a modem, a network interface card, and/or an antenna.

The device 900 may perform one or more operations or processes described herein. For example, a non-transitory computer-readable medium (e.g., memory 930) may store a set of instructions (e.g., one or more instructions or code) for execution by the processor 920. The processor 920 may execute the set of instructions to perform one or more operations or processes described herein. In some implementations, execution of the set of instructions, by one or more processors 920, causes the one or more processors 920 and/or the device 900 to perform one or more operations or processes described herein. In some implementations, hardwired circuitry may be used instead of or in combination with the instructions to perform one or more operations or processes described herein. Additionally, or alternatively, the processor 920 may be configured to perform one or more operations or processes described herein. Thus, implementations described herein are not limited to any specific combination of hardware circuitry and software.

The number and arrangement of components shown in FIG. 9 are provided as an example. The device 900 may include additional components, fewer components, different components, or differently arranged components than those shown in FIG. 9. Additionally, or alternatively, a set of components (e.g., one or more components) of the device 900 may perform one or more functions described as being performed by another set of components of the device 900.

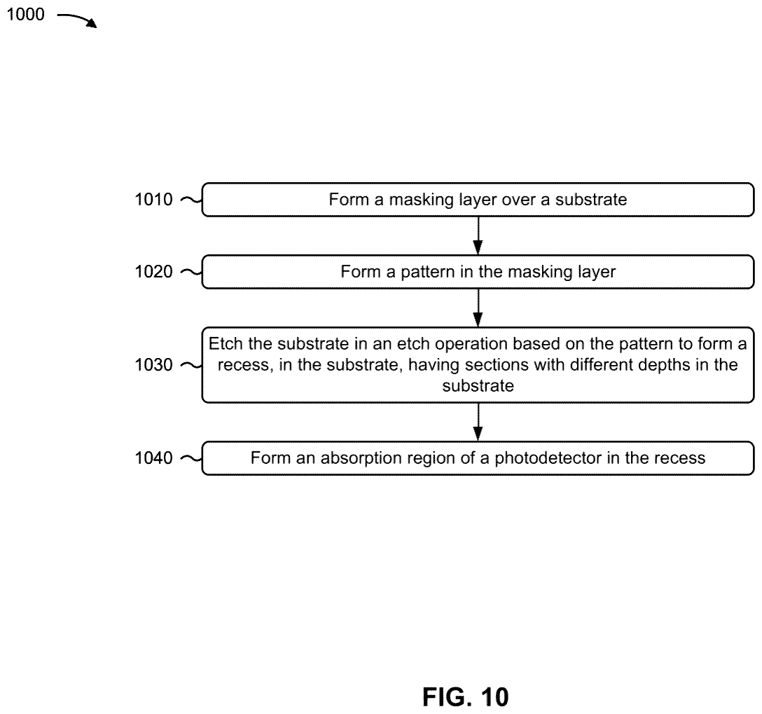

FIG. 10 is a flowchart of an example process 1000 associated with forming a photodetector device described herein. In some implementations, one or more process blocks of FIG. 10 are performed using one or more semiconductor processing tools (e.g., one or more semiconductor processing tools 102-114). Additionally, or alternatively, one or more process blocks of FIG. 10 may be performed using one or more components of device 900, such as processor 920, memory 930, input component 940, output component 950, and/or communication component 960.

As shown in FIG. 10, process 1000 may include forming a masking layer over a substrate (block 1010). For example, one or more semiconductor processing tools 102-114 may be used to form a masking layer (e.g., a masking layer 414, a masking layer 614) over a substrate (e.g., a semiconductor substrate 206), as described herein.

As further shown in FIG. 10, process 1000 may include forming a pattern in the masking layer (block 1020). For example, one or more semiconductor processing tools 102-114 may be used to form a pattern (e.g., a stepped pattern 418, a gradient pattern 618) in the masking layer, as described herein. In some implementations, the pattern includes a plurality of regions (e.g., regions 418a-418d, 618a, and/or 618b) of the masking layer that have different heights.

As further shown in FIG. 10, process 1000 may include etching the substrate in an etch operation based on the pattern to form a recess, in the substrate, having sections with different depths in the substrate (block 1030). For example, one or more semiconductor processing tools 102-114 may be used to etch the substrate in an etch operation based on the pattern to form a recess (e.g., a stepped recess 420, an angled recess 620), in the substrate, having sections (e.g., sections 420a-420d, sections 620a-620c) with different depths in the substrate, as described herein.

As further shown in FIG. 10, process 1000 may include forming an absorption region of a photodetector in the recess (block 1040). For example, one or more semiconductor processing tools 102-114 may be used to form an absorption region 208 of a photodetector in the recess, as described herein.

Process 1000 may include additional implementations, such as any single implementation or any combination of implementations described below and/or in connection with one or more other processes described elsewhere herein.

In a first implementation, forming the pattern in the masking layer includes forming a gradient pattern 618 in the masking layer.

In a second implementation, alone or in combination with the first implementation, forming the pattern in the masking layer includes forming a stepped pattern 418 in the masking layer.

In a third implementation, alone or in combination with one or more of the first and second implementations, the pattern in the masking layer is consumed in the etch operation, resulting in a gradual increase in an opening in the masking layer through which the substrate is etched.

In a fourth implementation, alone or in combination with one or more of the first through third implementations, the plurality of regions of the masking layer include a region (e.g., a region 418d, a region 618b) in which the masking layer is fully removed to expose the substrate through the masking layer.

In a fifth implementation, alone or in combination with one or more of the first through fourth implementations, the plurality of regions are arranged in the pattern such that the different heights decrease toward the region in which the masking layer is fully removed.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, a photodetector may include an absorption region that is formed to have an increasing depth (or thickness) in a direction that is approximately parallel to the direction of incident light that is to be projected onto the absorption region. The increasing depth of the absorption region in the direction that is approximately parallel with the direction of incident light enables the incident light to be more uniformly distributed along the length of the absorption region in the direction that is approximately parallel with the direction of incident light. This reduces the likelihood that a particular area of the absorption region reaches optical saturation, which may enable the photodetector to operate a sustained high photodetector sensitivity and/or a sustained high light detection performance, among other examples.

As described in greater detail above, some implementations described herein provide a photodetector device. The photodetector device includes a waveguide. The photodetector device includes a photodetector coupled with the waveguide. The photodetector includes an intrinsic semiconductor substrate that includes a first semiconductor material, a first type doped collection region in the intrinsic semiconductor substrate, a second type doped collection region in the intrinsic semiconductor substrate, and an absorption region in the semiconductor substrate between the first type doped collection region and the second type doped collection region. The absorption region includes a second semiconductor material. The absorption region includes a stepped profile or a tapered in a direction that is approximately parallel with a direction that the photodetector is to receive incident light from the waveguide.

As described in greater detail above, some implementations described herein provide a photodetector device. The photodetector device includes a waveguide. The photodetector device includes a photodetector coupled with the waveguide. The photodetector includes an intrinsic semiconductor substrate that includes a first semiconductor material, a first type doped collection region in the intrinsic semiconductor substrate, a second type doped collection region in the intrinsic semiconductor substrate, and an absorption region in the semiconductor substrate between the first type doped collection region and the second type doped collection region. The absorption region includes a second semiconductor material. The absorption region includes a tapered profile in a direction that is approximately parallel with a direction that the photodetector is to receive incident light from the waveguide.

As described in greater detail above, some implementations described herein provide a method. The method includes forming a masking layer over a substrate. The method includes forming a pattern in the masking layer, where the pattern includes a plurality of regions of the masking layer that have different heights. The method includes etching the substrate in an etch operation based on the pattern to form a recess, in the substrate, having sections with different depths in the substrate. The method includes forming an absorption region of a photodetector in the recess.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photodetector device, comprising:
a waveguide; and
a photodetector, coupled with the waveguide, comprising:
an intrinsic semiconductor substrate comprising a first semiconductor material;
a first type doped collection region in the intrinsic semiconductor substrate;
a second type doped collection region in the intrinsic semiconductor substrate; and
an absorption region, comprising a second semiconductor material, in the semiconductor substrate between the first type doped collection region and the second type doped collection region,
wherein the absorption region comprises a stepped profile or a tapered profile in a direction that is approximately parallel with a direction that the photodetector is to receive incident light from the waveguide.

2. The photodetector device of claim 1, wherein the absorption region comprises the stepped profile, and the stepped profile comprises a plurality of sections of increasing depth in the direction from which the photodetector is to receive the incident light.

3. The photodetector device of claim 2, wherein the plurality of sections comprises:
a first section configured to receive a first portion of the incident light;
a second section configured to receive a second portion of the incident light; and
a third section configured to receive a third portion of the incident light.

4. The photodetector device of claim 2, wherein a difference in depth between a first section and a second section of the plurality of sections is based on an optical confinement parameter associated with the absorption region.

5. The photodetector device of claim 1, wherein the absorption region is a first absorption region configured to absorb photons of a first wavelength range of the incident light; and
wherein the photodetector further comprises a second absorption region configured to absorb photons of a second wavelength range of the incident light,
wherein the first type doped collection region and the second type doped collection region are electrically coupled with the first absorption region and the second absorption region.

6. The photodetector device of claim 5, wherein the second absorption region comprises a third semiconductor material,
wherein the first semiconductor material, the second semiconductor material, and the third semiconductor material are different semiconductor materials.

7. The photodetector device of claim 1, wherein the absorption region is a first absorption region configured to absorb photons of a first wavelength range of the incident light;
wherein the first type doped collection region and the second type doped collection region are electrically coupled with the first absorption region; and
wherein the photodetector further comprises:
a third type doped collection region in the intrinsic semiconductor substrate;
a fourth type doped collection region in the intrinsic semiconductor substrate; and
a second absorption region, in the semiconductor substrate between the third type doped collection region and the fourth type doped collection region, configured to absorb photons of a second wavelength range of the incident light,
wherein the third type doped collection region and the fourth type doped collection region are electrically coupled with the second absorption region.

8. A photodetector device, comprising:
a waveguide; and
a photodetector, coupled with the waveguide, comprising:
an intrinsic semiconductor substrate comprising a first semiconductor material;
a first type doped collection region in the intrinsic semiconductor substrate;
a second type doped collection region in the intrinsic semiconductor substrate; and
an absorption region, comprising a second semiconductor material, in the semiconductor substrate between the first type doped collection region and the second type doped collection region,
wherein the absorption region comprises a tapered profile in a direction that is approximately parallel with a direction that the photodetector is to receive incident light from the waveguide.

9. The photodetector device of claim 8, wherein a depth of a sloped bottom surface of the absorption region increases in a sloped section from a first depth to a second depth in the direction that the photodetector is to receive the incident light.

10. The photodetector device of claim 9, wherein the sloped section is located between a first flat-bottomed section and a second flat-bottomed section in the direction that the photodetector is to receive the incident light.

11. The photodetector device of claim 8, wherein the absorption region is a first absorption region configured to absorb photons of a first wavelength range of the incident light; and
wherein the photodetector further comprises a second absorption region configured to absorb photons of a second wavelength range of the incident light,
wherein the first absorption region and the second absorption region are adjacent in the direction that the photodetector is to receive the incident light, and
wherein the first type doped collection region and the second type doped collection region are electrically coupled with the first absorption region and the second absorption region.

12. The photodetector of claim 11, wherein the second absorption region comprises another tapered profile.

13. The photodetector device of claim 8, wherein the absorption region is a first absorption region configured to absorb photons of a first wavelength range of the incident light;
wherein the first type doped collection region and the second type doped collection region are electrically coupled with the first absorption region; and
wherein the photodetector further comprises:
a third type doped collection region in the intrinsic semiconductor substrate;
a fourth type doped collection region in the intrinsic semiconductor substrate; and
a second absorption region, in the semiconductor substrate between the third type doped collection region and the fourth type doped collection region, configured to absorb photons of a second wavelength range of the incident light,
wherein the first absorption region and the second absorption region are adjacent in the direction that the photodetector is to receive the incident light,
wherein the second absorption region comprises another tapered profile, and
wherein the third type doped collection region and the fourth type doped collection region are electrically coupled with the second absorption region.

14. The photodetector device of claim 13, wherein the second absorption region comprises a third semiconductor material,
wherein the first semiconductor material, the second semiconductor material, and the third semiconductor material are different semiconductor materials.

15. A method, comprising:
forming a masking layer over a substrate;
forming a pattern in the masking layer,
wherein the pattern comprises a plurality of regions of the masking layer that have different heights;
etching the substrate in an etch operation based on the pattern to form a recess, in the substrate, having sections with different depths in the substrate; and
forming an absorption region of a photodetector in the recess.

16. The method of claim 15, wherein forming the pattern in the masking layer comprises:
forming a gradient pattern in the masking layer.

17. The method of claim 15, wherein forming the pattern in the masking layer comprises:
forming a stepped pattern in the masking layer.

18. The method of claim 15, wherein the pattern in the masking layer is consumed in the etch operation, resulting in a gradual increase in an opening in the masking layer through which the substrate is etched.

19. The method of claim 15, wherein the plurality of regions of the masking layer comprises a region in which the masking layer is fully removed to expose the substrate through the masking layer.

20. The method of claim 19, wherein the plurality of regions are arranged in the pattern such that the different heights decrease toward the region in which the masking layer is fully removed.
